(19) United States
(12) Patent Application Publication
(10) Pub. No.: US 2026/0136795 A1
(43) Pub. Date: May 14, 2026

(54) DISPLAY PANEL AND DISPLAYING DEVICE

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Dongdong Su, Beijing (CN); Yinhu Huang, Beijing (CN); Yuhao Lee, Beijing (CN); Bingming Feng, Beijing (CN); Xiaobin Shen, Beijing (CN); Lingang Wen, Beijing (CN); Fushuang Zhang, Beijing (CN); Junkai Yan, Beijing (CN); Jixing Wang, Beijing (CN); Jianming Zou, Beijing (CN); Ruquan Li, Beijing (CN); Xiong Yang, Beijing (CN); Chunchao Wang, Beijing (CN); Dacheng Zhang, Beijing (CN)

(73) Assignees: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(21) Appl. No.: 18/704,611

(22) PCT Filed: Jul. 25, 2023
(86) PCT No.: PCT/CN2023/109199

§ 371 Date: Apr. 25, 2024

(51) Int. Cl. H10K 59/35; H10K 59/12; H10K 59/80; H10K 102/00

(52) U.S. Cl. CPC H10K 59/35; H10K 59/1201; H10K 59/80518; H10K 59/879; H10K 2102/351

(57) ABSTRACT

A display panel and a displaying device are provided by the present application, which relate to the technical field of displaying. The display panel includes a first displaying region and a second displaying region. Each of the first displaying region and the second displaying region includes a driving base board and a plurality of sub-pixels that are located on the driving base board and are arranged in an array, and each of the sub-pixels includes a first electrode, an optical-adjustment layer, a luminescence-function layer and a second electrode that are sequentially arranged. For the sub-pixels of the same color,

$$\vert d 1 - \frac{n λ}{2 N 1} \vert > \vert d 2 - \frac{n λ}{2 N 2} \vert .$$

The display panel is suitable for the manufacturing of high-quality displaying devices.

### TECHNICAL FIELD

The present application relates to the technical field of displaying and, more particularly, to a display panel and a displaying device.

### BACKGROUND

With the rapid development of various techniques of displaying, people are having increasingly higher requirements on the sizes of display panels, and the sizes of display products are increasingly larger. In order to reduce the production cost, low sizes are stilled employed as the sizes of the masks that are required for the production of the display panels (in other words, the area of the effective exposure region in the mask is less than the displaying area of the display). In order to obtain the display panels of large sizes, the display panels of large sizes are manufactured by exposure by using spliced masks.

However, in the practical fabrication process, the splicing-exposure region might be exposed repeatedly, so that the exposure amount received by the splicing-exposure region is unequal to the exposure amount received by the region not with splicing exposure. Under the effect of the overlaying of the film layers of the display panel, the display panel very easily has the problem of ununiform brightness within the splicing-exposure region, the effect of displaying is reduced.

### SUMMARY

The following technical solutions are employed by the embodiments of the present application:

In a first aspect, a display panel is provided by an embodiment of the present application, wherein the display panel includes a first displaying region and a second displaying region; each of the first displaying region and the second displaying region includes a driving base board and a plurality of pixel units that are located on the driving base board and are arranged in an array, each of the plurality of pixel units includes a plurality of sub-pixels, and each of the plurality of the sub-pixels includes:
a first electrode configured to be capable of reflecting light rays;
an optical-adjustment layer located at one side of the first electrode;
a luminescence-function layer located at one side of the optical-adjustment layer away from the first electrode; and
a second electrode covering the luminescence-function layer and configured to be capable of transmitting and reflecting light rays; and
for the sub-pixels of a same color,

$$\vert d 1 - \frac{n λ}{2 N 1} \vert > \vert d 2 - \frac{n λ}{2 N 2} \vert ,$$

wherein d1 is a distance from the first electrode to the second electrode of the sub-pixels within the first displaying region, N1 is an effective refractive index from the first electrode to the second electrode of the sub-pixels within the first displaying region, n is a positive integer, λ is a peak wavelength of the color, d2 is a distance from the first electrode to the second electrode of each of the sub-pixels within the second displaying region, and N2 is an effective refractive index from the first electrode to the second electrode of the sub-pixels within the second displaying region.

In the at least one display panel according to the resent application, within the second displaying region, for the sub-pixels of the same color,

$$\vert d 2 - \frac{n λ}{2 N 2} \vert = 0.$$

In the at least one display panel according to the present application, for the sub-pixels of the same color, the effective refractive index from the first electrode to the second electrode of the sub-pixels within the first displaying region and the effective refractive index from the first electrode to the second electrode of the sub-pixels within the second displaying region are equal, and the distance from the first electrode to the second electrode of the sub-pixels within the first displaying region and the distance from the first electrode to the second electrode of the sub-pixels within the second displaying region are unequal.

In the at least one display panel according to the present application, for the sub-pixels of the same color, the distance from the first electrode to the second electrode of the sub-pixels within the first displaying region and the distance from the first electrode to the second electrode of the sub-pixels within the second displaying region are equal; and the effective refractive index from the first electrode to the second electrode of the sub-pixels within the first displaying region and the effective refractive index from the first electrode to the second electrode of the sub-pixels within the second displaying region are unequal.

In the at least one display panel according to the present application, the second displaying region is divided by the first displaying region into a third displaying sub-region and a fourth displaying sub-region that are discontinuous;
the first displaying region includes a middle region and edge regions located at two sides of the middle region, and the edge regions are adjacent to the third displaying sub-region or the fourth displaying sub-region; and
within the first displaying region, in directions from the middle region pointing to the edge regions, for the sub-pixels of the same color,

$$\vert d 1 - \frac{n λ}{2 N 1} \vert$$

gradually increases or gradually decreases.

In the at least one display panel according to the present application, in a direction from the first displaying region pointing to the third displaying sub-region, a quantity of the sub-pixels disposed within the first displaying region is less than or equal to 10.

In the at least one display panel according to the present application, the optical-adjustment layer includes a first optical-adjustment layer and a second optical-adjustment layer, the first optical-adjustment layer is located within the first displaying region, the second optical-adjustment layer is located within the second displaying region, and for some of the sub-pixels of the same color, a thickness of the first optical-adjustment layer and a thickness of the second optical-adjustment layer are unequal.

In the at least one display panel according to the present application, a reflectivity of a part of the driving base board that is located within the first displaying region is less than a reflectivity of a part of the driving base board that is located within the second displaying region.

In the at least one display panel according to the present application, an aperture ratio of a part of the display panel that is located within the first displaying region is greater than or equal to an aperture ratio of a part of the display panel that is located within the second displaying region.

In the at least one display panel according to the present application, each of the sub-pixels includes an auxiliary electrode, and the auxiliary electrode is located between the first electrode and the optical-adjustment layer; and
a transmittance of a part of the auxiliary electrode that is located within the first displaying region is less than or equal to a transmittance of a part of the auxiliary electrode that is located within the second displaying region.

In the at least one display panel according to the present application, for the sub-pixels of the same color, a refractive index of the first optical-adjustment layer is less than or equal to a refractive index of the second optical-adjustment layer.

In the at least one display panel according to the present application, the thickness of the first optical-adjustment layer or the thickness of the second optical-adjustment layer is zero.

In the at least one display panel according to the present application, each of the plurality of the pixel units includes a first sub-pixel, a second sub-pixel and a third sub-pixel, and the second optical-adjustment layer includes a first optical-adjustment pattern, a second optical-adjustment pattern and a third optical-adjustment pattern;
within the second displaying region, the first optical-adjustment pattern is located between the luminescence-function layer and the first electrode of the first sub-pixel, the second optical-adjustment pattern is located between the luminescence-function layer and the first electrode of the second sub-pixel, and the third optical-adjustment pattern is located between the luminescence-function layer and the first electrode of the third sub-pixel; and
a thickness of the first optical-adjustment pattern, a thickness of the second optical-adjustment pattern and a thickness of the third optical-adjustment pattern are at least partially unequal.

In the at least one display panel according to the present application, a refractive index of the first optical-adjustment pattern, a refractive index of the second optical-adjustment pattern and a refractive index of the third optical-adjustment pattern are at least partially unequal.

In the at least one display panel according to the present application, each of the first optical-adjustment pattern, the second optical-adjustment pattern and the third optical-adjustment pattern includes at least a conducting sub-layer; the conducting sub-layers are electrically connected to the first electrode, and there is a gap between the conducting sub-layers in two neighboring sub-pixels; and
at least one of the first optical-adjustment pattern, the second optical-adjustment pattern and the third optical-adjustment pattern further includes an inorganic sub-layer, and the inorganic sub-layer is located between the conducting sub-layer and the first electrode.

In the at least one display panel according to the present application, within the second displaying region, in a direction perpendicular to the luminescence-function layer, a distance from the first electrode to the second electrode of the first sub-pixel is a first distance; a distance from the first electrode to the second electrode of the second sub-pixel is a second distance; a distance from the first electrode to the second electrode of the third sub-pixel is a third distance;
wherein the first distance, the second distance and the third distance are at least partially unequal.

In the at least one display panel according to the present application, the first optical-adjustment pattern includes a first inorganic sub-layer, a second inorganic sub-layer, a third inorganic sub-layer and the conducting sub-layer that are located on the first electrode and are sequentially arranged; and
in the first sub-pixel within the second displaying region, the first optical-adjustment pattern further includes a first through hole, the first through hole extends throughout the first inorganic sub-layer, the second inorganic sub-layer and the third inorganic sub-layer, and the conducting sub-layer is electrically connected to the first electrode via the first through hole.

In the at least one display panel according to the present application, the second optical-adjustment pattern includes the first inorganic sub-layer, the second inorganic sub-layer and the conducting sub-layer that are located on the first electrode and are sequentially arranged; and
in the second sub-pixel within the second displaying region, the second optical-adjustment pattern further includes a second through hole, the second through hole extends throughout the first inorganic sub-layer and the second inorganic sub-layer, and the conducting sub-layer is electrically connected to the first electrode via the second through hole.

In the at least one display panel according to the present application, the third optical-adjustment pattern includes the conducting sub-layer located on the first electrode, and in the third sub-pixel within the second displaying region, the conducting sub-layer is contacted with and is connected to the first electrode.

In the at least one display panel according to the present application, a refractive index of the first inorganic sub-layer, a refractive index of the second inorganic sub-layer, a refractive index of the third inorganic sub-layer and a refractive index of the conducting sub-layer are unequal to each other.

In the at least one display panel according to the present application, in a direction away from the first electrode, the refractive index of the first inorganic sub-layer, the refractive index of the second inorganic sub-layer, the refractive index of the third inorganic sub-layer and the refractive index of the conducting sub-layer sequentially increase.

In the at least one display panel according to the present application, a material of the first inorganic sub-layer includes silicon oxide, a material of the second inorganic sub-layer includes aluminium oxide, a material of the third inorganic sub-layer includes silicon nitride, and a material of the conducting sub-layer includes indium tin oxide or indium zinc oxide.

In the at least one display panel according to the present application, the first optical-adjustment layer includes a fourth optical-adjustment pattern, a fifth optical-adjustment pattern and a sixth optical-adjustment pattern;
within the first displaying region, the fourth optical-adjustment pattern is located between the luminescence-function layer and the first electrode of the first sub-pixel, the fifth optical-adjustment pattern is located between the luminescence-function layer and the first electrode of the second sub-pixel, and the sixth optical-adjustment pattern is located between the luminescence-function layer and the first electrode of the third sub-pixel;
wherein a thickness of the fourth optical-adjustment pattern, a thickness of the fifth optical-adjustment pattern and a thickness of the sixth optical-adjustment pattern are substantially equal.

In the at least one display panel according to the present application, a material of the fourth optical-adjustment pattern, a material of the fifth optical-adjustment pattern and a material of the sixth optical-adjustment pattern are same, and are a light-transmitting conducting material; and
in the first sub-pixel within the first displaying region, the fourth optical-adjustment pattern is contacted with and is connected to the first electrode; in the second sub-pixel, the fifth optical-adjustment pattern is contacted with and is connected to the first electrode; and in the third sub-pixel, the sixth optical-adjustment pattern is contacted with and is connected to the first electrode.

In the at least one display panel according to the present application, the auxiliary electrode includes a first auxiliary sub-electrode and a second auxiliary sub-electrode, the first auxiliary sub-electrode is contacted with the first electrode, and the second auxiliary sub-electrode is contacted with the optical-adjustment layer; and a hardness of a material of the first auxiliary sub-electrode is greater than a hardness of a material of the first electrode.

In the at least one display panel according to the present application, each of the plurality of the sub-pixels further includes an auxiliary conducting layer and a protecting layer, the auxiliary conducting layer includes a third auxiliary sub-electrode and a fourth auxiliary sub-electrode, the third auxiliary sub-electrode is located between the first electrode and the fourth auxiliary sub-electrode, and the fourth auxiliary sub-electrode is contacted with and is conducted with the driving base board; the protecting layer covers a side face of the first electrode; and
a material of the third auxiliary sub-electrode is the same as a material of the first auxiliary sub-electrode.

In the at least one display panel according to the present application, the driving base board includes a plurality of metal layers, and each of the metal layers includes a plurality of conducting patterns; the first displaying region includes a first region, the second displaying region includes a second region, and the first region and the second region have a same shape and a same area; and
for at least one of the metal layers, an area of a part of the conducting patterns that is located within the first region is less than an area of a part of the conducting patterns that is located within the second region.

In the at least one display panel according to the present application, the display panel further includes a packing layer and a pixel defining layer, the packing layer is disposed between the first electrodes of two neighboring sub-pixels, and the optical-adjustment layer covers at least a part of the packing layer; the pixel defining layer is located at one side of all of the optical-adjustment layers away from the first electrode; and
the pixel defining layer includes a plurality of first slots arranged in an array, and at least a part of the luminescence-function layer is disposed in the first slots; and a region enclosed by an orthographic projection on the driving base board of an outer contour of the first slots falls within an orthographic projection of the optical-adjustment layer on the driving base board.

In the at least one display panel according to the present application, for the first slots of the luminescence-function layers provided with a same color, a size of a planar pattern of a part of the first slots located within the first displaying region is greater than or equal to a size of a planar pattern of a part of the first slots located within the second displaying region.

In the at least one display panel according to the present application, the pixel defining layer includes a plurality of second slots, each of the second slots is disposed between two neighboring first slots, and a depth of each of the second slots in a direction perpendicular to the driving base board is less than or equal to a depth of each of the first slots in the direction perpendicular to the driving base board.

In the at least one display panel according to the present application, the luminescence-function layer includes one luminescent sub-layer, and the second slots are configured to prevent color mixing of the luminescent sub-layers of the two neighboring sub-pixels.

In the at least one display panel according to the present application, wherein the luminescence-function layer includes at least two luminescent sub-layers, a charge generating layer is disposed between two neighboring luminescent sub-layers, and the second slots are configured to isolate the charge generating layers of the two neighboring sub-pixels.

In the at least one display panel according to the present application, the pixel defining layer includes a first sub-layer, a second sub-layer and a third sub-layer that are sequentially arranged in the direction away from the first electrode; and each of the second slots includes an opening and a bottom, and a size of the pattern enclosed by an edge of the opening is less than or equal to a size of a shape enclosed by an outer contour of the bottom.

In the at least one display panel according to the present application, the display panel further includes a packaging layer, a color light filtering layer and a lens layer, the packaging layer covers all of the second electrodes, the packaging layer includes at least two packaging sub-layers, and the color light filtering layer is located between two packaging sub-layers; and
the lens layer includes a plurality of lens components, the lens components are disposed within the first displaying region and/or the second displaying region, and the lens components are located at one side of the color light filtering layer away from the first electrode.

In the second aspect, an embodiment of the present application provides a displaying device, wherein the displaying device includes the display panel according to any one of the embodiments in the first aspect.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are merely embodiments of the present application, and a person skilled in the art can obtain other figures according to these figures without paying creative work.

FIG. 1 is a schematic diagram of abnormality of the displayed frame in the related art;

FIG. 2A is a diagram for illustrating the exposure mode of splicing exposure according to an embodiment of the present application;

FIG. 2B is a schematic diagram of distributing positions of the first displaying region and the second displaying region that are obtained by the mode of the splicing exposure shown in FIG. 2A;

FIG. 3 is a structural comparison diagram of the difference in the line widths of a part of the signal line in one of the metal layers of the driving base board that is located within the first displaying region and a part of a same type of signal line that is located within the second displaying region;

FIGS. 4, 7-11, 15-16 and 18 are schematic structural diagrams of the parts of nine types of the display panel according to the embodiments of the present application that are located within the second displaying region;

FIGS. 5, 6, 12-14, 17 and 19 are schematic structural diagrams of the parts of seven types of the display panel according to the embodiments of the present application that are located within the first displaying region;

FIG. 20 is a schematic top structural diagram of a display panel according to an embodiment of the present application;

FIG. 21 is a diagram of a trend of the variation of the difference in the line widths of the part of the signal line in the driving base board according to an embodiment of the present application that is located within the first displaying region and the part of the same type of signal line that is located within the second displaying region with the exposure amount; and

FIGS. 22A-26B are schematic diagrams of the intermediate structures in a process for manufacturing a display panel according to an embodiment of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first”, “second”, “third” and “fourth” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

In the description of the present disclosure, the terms “one embodiment”, “some embodiments”, “exemplary embodiment”, “example”, “specific example” or “some examples” are intended to indicate that specific features, structures, materials or characteristics related to the embodiment or example are included in at least one embodiment or example of the present application. The illustrative indication of the above terms does not necessarily refer to the same one embodiment or example. Moreover, the specific features, structures, materials or characteristics may be included in any one or more embodiments or examples in any suitable manner.

In the embodiments of the present application, the meaning of “plurality of” is “two or more”, and the meaning of “at least one” is “one or more”, unless explicitly and particularly defined otherwise.

All of the features used in the embodiments of the present application of “parallel”, “perpendicular”, “the same” and so on include the features of “parallel”, “perpendicular”, “the same” and so on in the strict sense, and include the cases in which there is a certain tolerance such as “substantially parallel”, “substantially perpendicular” and “substantially the same”, taking into consideration the measurement and the tolerances relevant to the measurement on particular quantities (for example, restricted by the measuring system), and represent that they are in the acceptable deviation ranges of the particular values determined by a person skilled in the art. For example, the “substantially” can represent that they are within one or more standard deviations, or within 10% or 5% of the values.

Unless stated otherwise in the context, throughout the description and the claims, the term “include” is interpreted as the meaning of opened containing, i.e., “including but not limited to”.

The “same one layer” according to the embodiments of the present application refers to the relation between multiple film layers that are formed by using the same one material after the same one step (for example, a one-step patterning step). The “same one layer” used herein does not always refer to that the thickness of a plurality of film layers are equal or that the heights in a cross-sectional view of a plurality of film layers are equal. The polygons in the description are not the strictly defined polygons, may be an approximate triangle, parallelogram, trapezoid, pentagon, hexagon and so on, and may have some small deformations caused by tolerance.

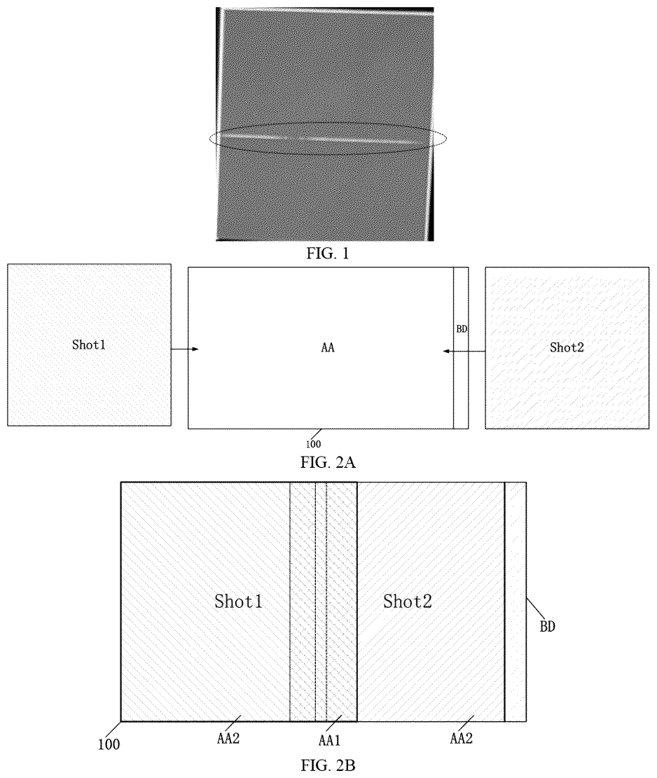

In order to reduce the production cost, low sizes are stilled employed as the sizes of the masks that are required for the production of the display panels (in other words, the area of the effective exposure region in the mask is less than the displaying area of the display). In order to obtain the display panels of large sizes, the display panels of large sizes are manufactured by exposure by using spliced masks. For example, as shown in FIG. 2A, the exposure region on the driving base board 100 of the exposure lens of the exposure machine corresponds to the region Shot1 or the region Shot2. In the practical fabrication process, the splicing-exposure region might be exposed repeatedly. For example, the region shown in FIG. 2B where the region Shot1 and the region Shot2 overlap is the splicing-exposure region. The exposure amount received by the splicing-exposure region is unequal to the exposure amount received by the region not with splicing exposure. Under the effect of the overlaying of the film layers of the display panel, the display panel very easily has the problem of ununiform brightness within the splicing-exposure region, for example, the splicing Mura shown by the dotted-line circle in FIG. 1, the effect of displaying is reduced.

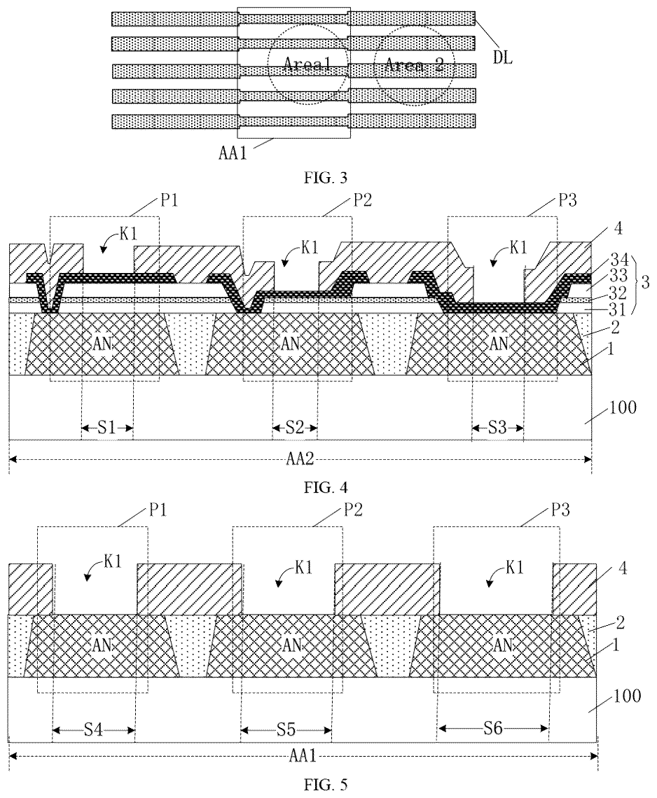

In view of this, a display panel is provided by an embodiment of the present application. As shown in FIG. 2B, the display panel includes a first displaying region AA1 and a second displaying region AA2. Each of the first displaying region AA1 and the second displaying region AA2 includes a driving base board 100 and a plurality of pixel units that are located on the driving base board 100 and are arranged in an array, and each of the pixel units includes a plurality of sub-pixels. Referring to FIGS. 4, 5, 6, 14, 15, 16 and 17, each of the plurality of sub-pixels includes:
a first electrode 1 configured to be capable of reflecting light rays;
an optical-adjustment layer 3 located at one side of the first electrode 1;
a luminescence-function layer 5 located at the side of the optical-adjustment layer 3 away from the first electrode 1; and
a second electrode 6 covering the luminescence-function layer 5 and configured to be capable of transmitting and reflecting light rays.

For the sub-pixels of a same color,

$$\vert d 1 − \frac{n λ}{2 N 1} \vert > \vert d 2 − \frac{n λ}{2 N 2} \vert ,$$

wherein d1 is a distance from the first electrode 1 to the second electrode 6 of the sub-pixels within the first displaying region AA1, N1 is an effective refractive index from the first electrode 1 to the second electrode 6 of the sub-pixels within the first displaying region AA1, n is a positive integer, λ is a peak wavelength of the color, d2 is a distance from the first electrode 1 to the second electrode 2 of the sub-pixels within the second displaying region AA2, and N2 is an effective refractive index from the first electrode 1 to the second electrode 2 of the sub-pixels within the second displaying region AA2.

In an exemplary embodiment, one of the first displaying region AA1 and the second displaying region AA2 stated above is the region of the display panel that corresponds to the splicing exposure, and the other is the region that corresponds to the normal exposure. As an example, the first displaying region AA1 is the region of the display panel that corresponds to the splicing exposure.

Both of the first displaying region AA1 and the second displaying region AA2 are the regions used to display frames.

In an exemplary embodiment, the display panel may be an organic light emitting diode (OLED) display panel.

The position relation between the first displaying region AA1 and the second displaying region AA2 is not limited herein, and is particularly related to the mode of the splicing exposure.

As an example, the region that corresponds to the splicing exposure is located between two neighboring regions that correspond to the normal exposure. For example, the first displaying region AA1 is the region that corresponds to the splicing exposure, the second displaying region AA2 is the region that corresponds to the normal exposure, and the first displaying region AA1 is located between two neighboring second displaying regions AA2.

The size relation between the first displaying region AA1 and the second displaying region AA2 is not limited herein, and is particularly related to the mode of the splicing exposure and the size of the display panel.

As an example, taking the case as an example where the first displaying region AA1 is the region that corresponds to the splicing exposure and the second displaying region AA2 is the region that corresponds to the normal exposure, the area of the first displaying region AA1 is far less than the area of the second displaying region AA2.

The specific structure of the driving circuit in the driving base board 100 is not limited herein, and may be decided according to the type of the product.

The substrate of the driving baseboard 100 is not limited herein.

In some examples, the substrate may be manufactured by using one or more of glass, polyimide, polycarbonate, polyacrylate, polyetherimide and polyether sulfone, and the present embodiment includes but is not limited thereto.

In some examples, the substrate may be a rigid substrate or a flexible substrate.

When the substrate is a flexible substrate, the substrate may include a single flexible-material layer, or the substrate 100 may include a first flexible-material layer, a first inorganic-non-metallic-material layer, a second flexible-material layer and a second inorganic-non-metallic-material layer that are sequentially arranged in layer configuration. The materials such as polyimide (PI), polyethylene terephthalate (PET) and a surface-treated polymer soft film are employed as the materials of the first flexible-material layer and the second flexible-material layer. Silicon nitride (SiNₓ), silicon oxide (SiOₓ) and so on are employed as the materials of the first inorganic-non-metallic-material layer and the second inorganic-non-metallic-material layer, to improve the capacity of the substrate of resisting water and oxygen. The first inorganic-non-metallic-material layer and the second inorganic-non-metallic-material layer are also referred to as barrier layers.

When the substrate is a rigid substrate, the substrate may include a glass substrate or a silicon-material substrate.

When the substrate of the driving base board 100 is a silicon-material substrate, the driving base board 100 is a silicon-based driving base board.

In an exemplary embodiment, each of the sub-pixels includes a light emitting device, and the light emitting device includes the luminescence-function layer 5 and the first electrode 1 and the second electrode 6 that are located at the two sides of the luminescence-function layer 5. The first electrode 1 is located between the luminescence-function layer 5 and the driving base board 100, and at least a part of the second electrode 6 is located at the side of the luminescence-function layer 5 away from the driving base board 100.

In an exemplary embodiment, the luminescence-function layer 5 includes a plurality of functional sub-layers. It should be noted that the luminescence-function layer 5 does not only include the film layer that directly emits light, but also includes the functional film layers for assisting the light emission, for example, a hole transporting layer and an electron transporting layer.

In some examples, a metal material, for example, any one or more of magnesium (Mg), silver (Ag), copper (Cu), aluminum (Al), titanium (Ti) and molybdenum (Mo), or an alloy material of the above-described metals, for example, an aluminum-neodymium alloy (AlNd) or a molybdenum-niobium alloy (MoNb) may be employed as the first electrode 1.

In some examples, any one or more of magnesium (Mg), silver (Ag) and aluminum (Al), or an alloy prepared by using any one or more of the above-described metals, or a transparent conducting material may be employed as the second electrode 6.

As an example, the first electrode 1 may be the anode, and the second electrode 2 may be the cathode. The plurality of sub-pixels may share the second electrode 2. For example, the cathode may be formed by using a high-electric-conductivity low-work-function material. For example, the cathode may be manufactured by using a metal material. For example, the anode may be formed by using a transparent conducting material having a high work function.

The optical-adjustment layer 3 includes at least a light-transmitting conducting material; for example, it includes indium tin oxide or indium zinc oxide.

In some embodiments, the optical-adjustment layer 3 further includes a non-conducting material.

Whether the thicknesses of the optical-adjustment layers 3 of the different sub-pixels in the same pixel unit are equal is not limited herein.

As an example, the thicknesses of the optical-adjustment layers 3 of the different sub-pixels in the same pixel unit are partially equal.

As an example, all of the thicknesses of the optical-adjustment layers 3 of the different sub-pixels in the same pixel unit are equal.

As an example, all of the thicknesses of the optical-adjustment layers 3 of the different sub-pixels in the same pixel unit are unequal.

In some embodiments, all of the displaying colors of the sub-pixels may be the same. For example, all of the sub-pixels display the blue color. As another example, all of the sub-pixels display the white color.

In some other embodiments, the display panel may include multiple types of the sub-pixels of different displaying colors. For example, the display panel may include all of three types of the sub-pixels that display the red color, the blue color and the green color. As another example, the display panel may include all of four types of the sub-pixels that display the red color, the blue color, the green color and the white color.

That the thicknesses of at least some of the optical-adjustment layers 3 are unequal includes but is not limited to the following cases:

In a first case, for the sub-pixels of the same color, the thicknesses of some of the optical-adjustment layers 3 of the sub-pixels are unequal, and the thicknesses of some of the optical-adjustment layers 3 are equal.

In a second case, for the sub-pixels of the same color, all of the thicknesses of the optical-adjustment layers 3 of the sub-pixels are unequal.

In a third case, for the sub-pixels of different colors, the thicknesses of some of the optical-adjustment layers 3 of the sub-pixels are unequal, and the thicknesses of some of the optical-adjustment layers 3 are equal.

In a fourth case, for the sub-pixels of different colors, the thicknesses of some of the optical-adjustment layers 3 of the sub-pixels are unequal.

In a fifth case, for the sub-pixels of different colors, the thicknesses of some of the optical-adjustment layers 3 of the sub-pixels are equal.

That an aperture ratio of a part of the display panel that is located within the first displaying region AA1 and an aperture ratio of a part of the display panel that is located within the second displaying region AA2 are unequal includes the following cases: the aperture ratio of the part of the display panel that is located within the first displaying region AA1 is greater than the aperture ratio of the part of the display panel that is located within the second displaying region AA2. Alternatively, the aperture ratio of the part of the display panel that is located within the first displaying region AA1 is less than the aperture ratio of the part of the display panel that is located within the second displaying region AA2.

The aperture ratio refers to a ratio of the effective light-transmitting region of the display panel to an area of the whole of the displaying region. Herein, the aperture ratio of the first displaying region AA1 refers to a ratio of the effective light-transmitting region within the first displaying region AA1 to an area of the first displaying region AA1, and the aperture ratio of the second displaying region AA2 refers to a ratio of the effective light-transmitting region within the second displaying region AA2 to an area of the second displaying region AA2. The effective light-transmitting region refers to the area where the displaying light rays practically transmit.

In the embodiments of the present application, for the sub-pixels of the same color, the sub-pixels within the first displaying region AA1 and the sub-pixels within the second displaying region AA2 have micro-cavity effects of unequal degrees, and the difference in the brightnesses of the first displaying region AA1 and the second displaying region AA2 are adjusted by using the micro-cavity effects of unequal degrees, so that the brightnesses of the first displaying region AA1 and the second displaying region AA2 of the display panel tend to be equal, to improve the effect of displaying.

The effective cavity length of the micro-cavity effect is decided mainly by the distance d from the first electrode 1 to the second electrode 6 and the effective refractive index N from the first electrode 1 to the second electrode 6.

For the sub-pixels of the same color, within the first displaying region AA1, the effective cavity length of the micro-cavity effect formed in the sub-pixels is

$$\vert d 1 − \frac{n λ}{2 N 1} \vert ,$$

and within the second displaying region AA2, the effective cavity length of the micro-cavity effect formed in the sub-pixels is

$$\vert d 2 − \frac{n λ}{2 N 2} \vert .$$

The effective cavity length may also be referred to as the optical distance.

Because the distance from the first electrode 1 to the second electrode 6 of the sub-pixels is decided mainly by the thickness of the optical-adjustment layer 3 and the thickness of the luminescence-function layer 5, and for the sub-pixels of the same color, the thickness of the luminescence-function layers 5 are usually equal, and it can be known according to the above formulas that the main factors that influence the effective cavity length of the micro-cavity effect is the thickness of the optical-adjustment layer 3 and the effective refractive index from the first electrode 1 to the second electrode 6.

In the embodiments of the present application, when the first displaying region AA1 is the region that is manufactured by using the splicing exposure, the first displaying region AA1 has a higher brightness. By configuring that, for the sub-pixels of the same color,

$$\vert d 1 − \frac{n λ}{2 N 1} \vert > \vert d 2 − \frac{n λ}{2 N 2} \vert ,$$

i.e., by configuring that the effective cavity length of the sub-pixels located within the first displaying region AA1 is greater than the effective cavity length of the sub-pixels located within the second displaying region AA2, that enables the micro-cavity effect of the sub-pixels located within the first displaying region AA1 to be the weaker micro-cavity effect, and the micro-cavity effect of the sub-pixels located within the second displaying region AA2 to be the stronger micro-cavity effect, to increase the displaying brightness of the second displaying region AA2 to a large extent. Therefore, regulating the brightnesses of the different regions by the degrees of the micro-cavity effects is realized, so that the influence on the brightness by the micro-cavity effect and the influence on the brightness by the aperture ratio reach a balance, which finally causes the displaying brightness of the part of the display panel that is located within the first displaying region AA1 and the displaying brightness of the part of the display panel that is located within the second displaying region AA2 to be equal, thereby the uniformity of the brightness of the display panel is increased, and the effect of displaying is improved.

It should be noted that, when the first displaying region AA1 is the region that is manufactured by using the splicing exposure, and the second displaying region AA2 is the region that is manufactured by using the normal exposure, the aperture ratio of the first displaying region AA1 is greater than the aperture ratio of the second displaying region AA2.

In the at least one display panel according to the present application, within the second displaying region AA2, for the sub-pixels of the same color,

$$\vert d 2 − \frac{n λ}{2 N 2} \vert = 0.$$

In some embodiments of the present application, when all of the colors of the sub-pixels included by the display panel are the same, it may be configured that the effective cavity length of the optical micro-cavity formed in the sub-pixels within the second displaying region AA2 is zero, so that the micro-cavity effect of the sub-pixels within the second displaying region AA2 is as large as possible, to increase the displaying brightness of the sub-pixels within the second displaying region AA2, so that the display panel has a higher brightness uniformity, the effect of displaying is improved. It should be noted that, when all of the colors of the sub-pixels included by the display panel are the same, the display panel may be used as a backlight module, and the light source supplied by the backlight module has a very good brightness uniformity.

In some embodiments of the present application, when the display panel includes sub-pixels of different colors at the same time, for example, including sub-pixels of the red color, the green color and the blue color at the same time, for the sub-pixels of the same color, it may be configured that the effective cavity length of the optical micro-cavity formed in the sub-pixels within the second displaying region AA2 is zero, so that the micro-cavity effect of the sub-pixels within the second displaying region AA2 is as large as possible, to increase the displaying brightness of the sub-pixels within the second displaying region AA2, so that the display panel has a higher brightness uniformity, thereby the quality of the frames when the display panel displays frames is improved, and the problem of frame abnormality caused by a nonuniform brightness is ameliorated.

As stated above, because the effective cavity length of the micro-cavity effect is decided mainly by the distance d from the first electrode 1 to the second electrode 6 and the effective refractive index N from the first electrode 1 to the second electrode 6, for the sub-pixels of the same color,

$$\vert d 1 − \frac{n λ}{2 N 1} \vert > \vert d 2 − \frac{n λ}{2 N 2} \vert$$

includes the following cases:

In the first case, for the sub-pixels of the same color, the effective refractive index N1 from the first electrode 1 to the second electrode 6 of the sub-pixels within the first displaying region AA1 and the effective refractive index N2 from the first electrode 1 to the second electrode 6 of the sub-pixels within the second displaying region AA2 are equal, and the distance d1 from the first electrode 1 to the second electrode 6 of the sub-pixels within the first displaying region AA1 and the distance d2 from the first electrode 1 to the second electrode 6 of the sub-pixels within the second displaying region AA2 are unequal.

In the second case, for the sub-pixels of the same color, the distance d1 from the first electrode 1 to the second electrode 6 of the sub-pixels within the first displaying region AA1 and the distance d2 from the first electrode 1 to the second electrode 6 of the sub-pixels within the second displaying region AA2 are equal; and the effective refractive index N1 from the first electrode 1 to the second electrode 2 of the sub-pixels within the first displaying region AA1 and the effective refractive index N2 from the first electrode 1 to the second electrode 2 of the sub-pixels within the second displaying region AA2 are unequal.

In the third case, the distance d1 from the first electrode 1 to the second electrode 6 of the sub-pixels within the first displaying region AA1 and the distance d2 from the first electrode 1 to the second electrode 6 of the sub-pixels within the second displaying region AA2 are unequal, and the effective refractive index N1 from the first electrode 1 to the second electrode 2 of the sub-pixels within the first displaying region AA1 and the effective refractive index N2 from the first electrode 1 to the second electrode 2 of the sub-pixels within the second displaying region AA2 are unequal. In the at least one display panel according to the present application, as shown in FIG. 2B, the second displaying region AA2 is divided by the first displaying region AA1 into a third displaying sub-region (for example, the part of the second displaying region AA2 that is located at the left side of the first displaying region AA1 in FIG. 2B) and a fourth displaying sub-region (for example, the part of the second displaying region AA2 that is located at the right side of the first displaying region AA1 in FIG. 2B) that are discontinuous.

The first displaying region AA1 includes a middle region (for example, the region where the dotted-line rectangle is located in FIG. 2B) and edge regions located at the two sides of the middle region, and the edge regions are adjacent to the third displaying sub-region or the fourth displaying sub-region.

In some embodiments, the middle region includes at least one row of the sub-pixels.

Within the first displaying region AA1, for the sub-pixels of the same color, the effective cavity length

$$\vert d 1 − \frac{n λ}{2 N 1} \vert$$

of the middle region is greater than or less than the effective cavity length

$$\vert d 1 − \frac{n λ}{2 N 1} \vert$$

of the edge regions.

As an example, within the first displaying region AA1, in the directions from the middle region pointing to the edge regions, for the sub-pixels of the same color,

$$\vert d 1 − \frac{n λ}{2 N 1} \vert$$

gradually increases or gradually decreases.

In practical applications, within the first displaying region AA1 that corresponds to the splicing exposure, the middle region and the edge regions of the first displaying region AA1 might have a difference in the brightnesses. When the middle region has a higher brightness and the edge regions have a lower brightness, it may be configured that, within the first displaying region AA1, in the directions from the middle region pointing to the edge regions, for the sub-pixels of the same color,

$$\vert d 1 − \frac{n λ}{2 N 1} \vert$$

gradually decreases, so that the sub-pixels within the edge regions have the stronger micro-cavity effect, to increase the brightness of the sub-pixels within the edge regions, thereby the brightness uniformity of the display panel is improved.

When the middle region has a lower brightness and the edge regions have a higher brightness, it may be configured that, within the first displaying region AA1, in the directions from the middle region pointing to the edge regions, for the sub-pixels of the same color,

$$\vert d 1 − \frac{n λ}{2 N 1} \vert$$

gradually increases, so that the sub-pixels within the middle region have the stronger micro-cavity effect, to increase the brightness of the sub-pixels within the middle region, thereby the brightness uniformity of the display panel is improved.

In the at least one display panel according to the present application, in a direction from the first displaying region AA1 pointing to the third displaying sub-region, a quantity of the sub-pixels disposed within the first displaying region AA1 is less than or equal to 10.

In the direction from the first displaying region AA1 pointing to the third displaying sub-region, the quantity of the sub-pixels disposed within the first displaying region AA1 is less than or equal to 10. In other words, at least one row of the sub-pixels may be disposed within the first displaying region AA1, and the row quantity of the sub-pixels is less than or equal to 10.

As an example, in the direction from the first displaying region AA1 pointing to the third displaying sub-region, the quantity of the sub-pixels disposed within the first displaying region AA1 may be 1, 2, 3, 4, 5, 6, 7, 8 and 9.

In the at least one display panel according to the present application, the optical-adjustment layer 3 includes a first optical-adjustment layer and a second optical-adjustment layer, the first optical-adjustment layer is located within the first displaying region AA1, the second optical-adjustment layer is located within the second displaying region AA2, and for some of the sub-pixels of the same color, the thickness of the first optical-adjustment layer and the thickness of the second optical-adjustment layer are unequal.

In an exemplary embodiment, the sub-pixels includes a first sub-pixel P1, a second sub-pixel P2 and a third sub-pixel P3, wherein the colors of the first sub-pixel P1, the second sub-pixel P2 and the third sub-pixel P3 are different. For some of the sub-pixels of the same color, the thickness of the first optical-adjustment layer and the thickness of the second optical-adjustment layer are unequal. For some of the sub-pixels of the same color, the thickness of the first optical-adjustment layer and the thickness of the second optical-adjustment layer are equal.

For example, referring to FIGS. 4 and 5, for the first sub-pixels P1, the thicknesses of the first optical-adjustment layer of the first sub-pixel P1 within the first displaying region AA1 and the second optical-adjustment layer of the first sub-pixel P1 within the second displaying region AA2 are unequal.

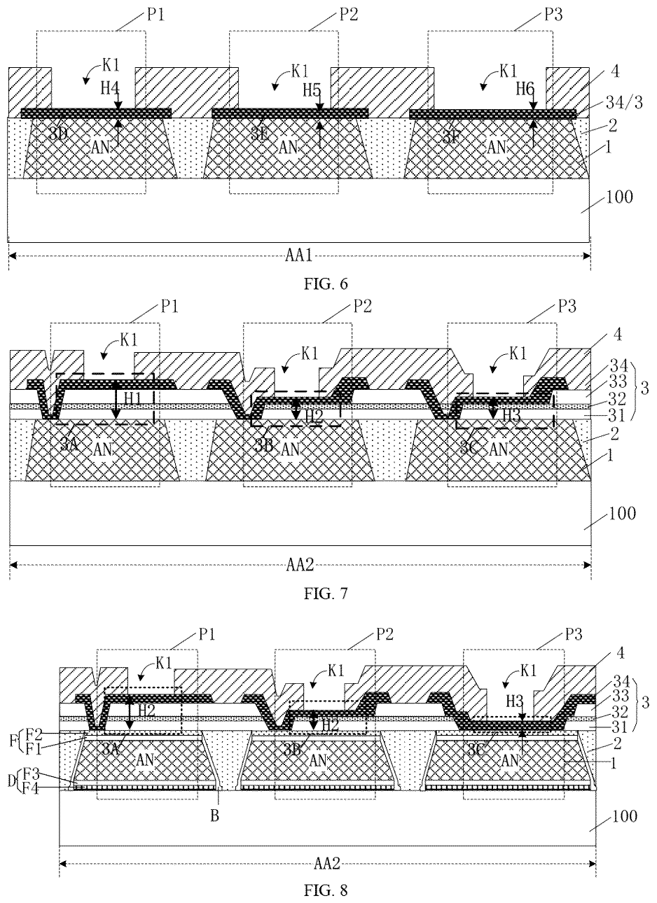

For example, referring to FIGS. 4 and 5 (or referring to FIGS. 4 and 6), for the second sub-pixels P2, the thicknesses of the first optical-adjustment layer of the second sub-pixel P2 within the first displaying region AA1 and the second optical-adjustment layer of the second sub-pixel P2 within the second displaying region AA2 are unequal.

For example, referring to FIGS. 4 and 6, for the third sub-pixels P3, the thicknesses of the first optical-adjustment layer of the third sub-pixel P3 within the first displaying region AA1 and the second optical-adjustment layer of the third sub-pixel P3 within the second displaying region AA2 are equal.

In the at least one display panel according to the present application, a reflectivity of a part of the driving base board 100 that is located within the first displaying region AA1 is less than a reflectivity of a part of the driving base board 100 that is located within the second displaying region AA2.

In an exemplary embodiment, the main component of the driving base board 100 is the pixel driving circuit formed by conducting patterns. The conducting patterns are manufactured by using a metal material. When the proportion of the area of the conducting patterns is higher, the metal light-reflection effect of the region where the conducting patterns are located is more significant, and accordingly the reflectivity is higher.

The film layers or the structures of the pixel driving circuit (for example, including the components such as a thin-film transistor and a storage capacitor), such as a data line, a gate line, a power-signal line, a resetting power-signal line, a resetting controlling-signal line and a light-emission controlling-signal line, may refer to the description in the related art, and are not limited herein.

In an exemplary embodiment, the first displaying region AA1 is the splicing-exposure region.

Within the region that is manufactured by the splicing exposure, because a positive photoresist is usually employed in the exposure and the etching of metals, in the etching processes employing a positive photoresist, when the exposure amount is higher, the gap (Space) between the formed conducting patterns is higher, so that the sizes of the conducting patterns themselves are lower. For example, when the conducting patterns are the signal lines, when the exposure amount is higher, the line width of the signal lines is lower. Because the splicing-exposure region are exposed repeatedly, it has a higher exposure amount, and therefore the gap between the conducting patterns formed within the splicing-exposure region is higher, the conducting patterns themselves have lower sizes, to result in a lower reflectivity of the splicing-exposure region.

In the at least one display panel according to the present application, the aperture ratio of the part of the display panel that is located within the first displaying region AA1 is greater than or equal to the aperture ratio of the part of the display panel that is located within the second displaying region AA2.

In an exemplary embodiment, the aperture ratio of the OLED display panel is decided mainly by the size of the pixel opening of the pixel defining layer PDL where the luminescence-function layer 5 is disposed. At least a part of the area of the luminescence-function layer 5 is disposed in the pixel opening of the pixel defining layer PDL. When the size of the pixel opening is higher, the area of the effective light emitting region is higher, and the aperture ratio is higher.

In an exemplary embodiment, the first displaying region AA1 is the splicing-exposure region.

Within the region that is manufactured by the splicing exposure, because a positive photoresist is usually employed in the exposure and the etching of the pixel defining layer PDL, in the etching processes employing a positive photoresist, when the exposure amount is higher, the size of the formed opening (Space) is higher. Because the splicing-exposure region are exposed repeatedly, it has a higher exposure amount, and the size of the pixel opening of the formed pixel defining layer PDL is higher, so that the aperture ratio is higher. When the first displaying region AA1 is the splicing-exposure region, the aperture ratio of the part of the display panel that is located within the first displaying region AA1 is greater than the aperture ratio of the part of the display panel that is located within the second displaying region AA2.

In the at least one display panel according to the present application, as shown in FIG. 8, each of the sub-pixels includes an auxiliary electrode F, and the auxiliary electrode F is located between the first electrode 1 and the optical-adjustment layer 3.

The transmittance of the part of the auxiliary electrode F that is located within the first displaying region AA1 is less than or equal to the transmittance of the part of the auxiliary electrode F that is located within the second displaying region AA2.

In the embodiments of the present application, taking the case as an example where the first displaying region AA1 is the splicing-exposure region, when the aperture ratio of the first displaying region AA1 is greater than the aperture ratio of the second displaying region AA2, because, when the other influencing factors are the same, when the aperture ratio is higher, the brightness is higher, in order to further adjust the brightness uniformity of the display panel, it may be configured that the transmittance of the part of the auxiliary electrode F that is located within the first displaying region AA1 is less than or equal to the transmittance of the part of the auxiliary electrode F that is located within the second displaying region AA2. In this way, the transmittance of the part of the auxiliary electrode F that is located within the second displaying region AA2 can be further increased, thereby the displaying brightness of the second displaying region AA2 is increased, so that the brightnesses of the first displaying region AA1 and the second displaying region AA2 tend to be equal, thereby the effect of displaying of the display panel is improved.

In the at least one display panel according to the present application, for the sub-pixels of the same color, a refractive index of the first optical-adjustment layer is less than or equal to a refractive index of the second optical-adjustment layer. In other words, for the sub-pixels of the same color, the refractive index of the optical-adjustment layer 3 of the sub-pixels located within the first displaying region AA1 is less than or equal to the refractive index of the optical-adjustment layer 3 of the sub-pixels located within the second displaying region AA2.

In at least one display panel according to the embodiments of the present application, by configuring that, for the sub-pixels of the same color, the refractive index of the optical-adjustment layer 3 of the sub-pixels located within the first displaying region AA1 is less than or equal to the refractive index of the optical-adjustment layer 3 of the sub-pixels located within the second displaying region AA2. In this way, when the refractive index is lower, the degree of the micro-cavity effect is weaker, which can further increase the brightness of the displaying light rays within the second displaying region AA2, so that the brightnesses of the first displaying region AA1 and the second displaying region AA2 tend to be equal, thereby the effect of displaying of the display panel is improved.

In the at least one display panel according to the present application, the thickness of the first optical-adjustment layer or the thickness of the second optical-adjustment layer is zero.

As an example, the optical-adjustment layer 3 may not be disposed (in other words, the thickness of the first optical-adjustment layer is zero) within the first displaying region AA1. Alternatively, the optical-adjustment layer 3 may not be disposed (in other words, the thickness of the second optical-adjustment layer is zero) within the second displaying region AA2.

As an example, as shown in FIG. 5, the optical-adjustment layer 3 may not be disposed (in other words, the thickness of the first optical-adjustment layer is zero) within the first displaying region AA1.

In the embodiments of the present application, taking the case as an example where the first displaying region AA1 is the splicing-exposure region, by not disposing the optical-adjustment layer 3 within the first displaying region AA1, and disposing the optical-adjustment layer 3 within the second displaying region AA2, the micro-cavity effect is formed within the second displaying region AA2. By regulating the degree of the micro-cavity effect by regulating the thickness of the optical-adjustment layer 3, the brightness of the displaying light rays within the second displaying region AA2 is increased to a large extent, so that the brightnesses of the first displaying region AA1 and the second displaying region AA2 tend to be equal, thereby the effect of displaying of the display panel is improved.

In the at least one display panel according to the present application, as shown in FIGS. 4, 7, 8, 9, 10 and 11, each of the pixel units includes a first sub-pixel P1, a second sub-pixel P2 and a third sub-pixel P3, and the second optical-adjustment layer includes a first optical-adjustment pattern 3A, a second optical-adjustment pattern 3B and a third optical-adjustment pattern 3C.

As an example, the first sub-pixel P1 is a sub-pixel of a first color, the second sub-pixel P2 is a sub-pixel of a second color, and the third sub-pixel P3 is a sub-pixel of a third color.

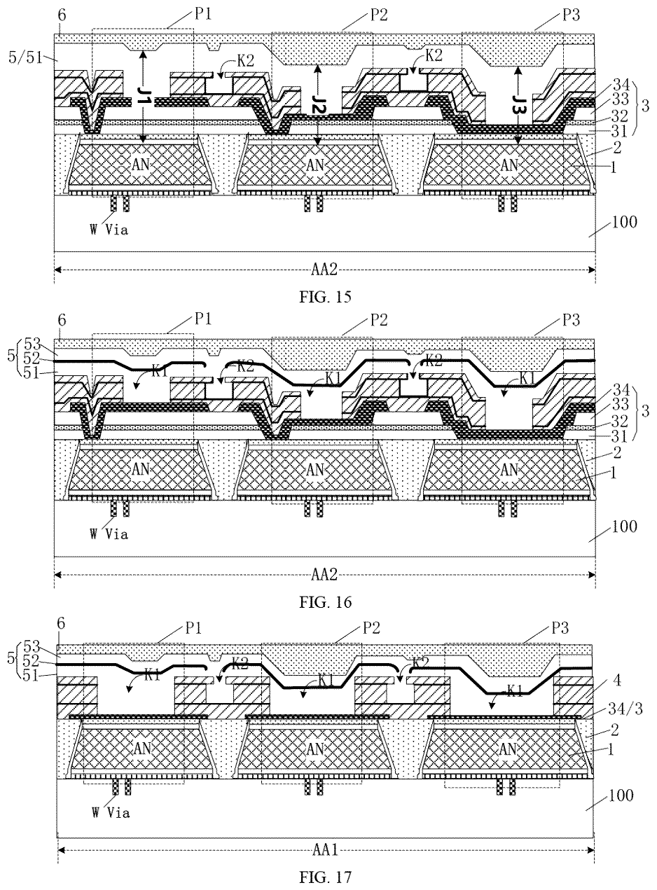

Referring to FIG. 15 or FIG. 16, within the second displaying region AA2, the first optical-adjustment pattern 3A is located between the luminescence-function layer 5 and the first electrode 6 of the first sub-pixel P1, the second optical-adjustment pattern 3B is located between the luminescence-function layer 5 and the first electrode 6 of the second sub-pixel P2, and the third optical-adjustment pattern 3C is located between the luminescence-function layer 5 and the first electrode 6 of the third sub-pixel P3. The thickness of the first optical-adjustment pattern 3A, the thickness of the second optical-adjustment pattern 3B and the thickness of the third optical-adjustment pattern 3C are at least partially unequal.

In some examples, the luminous efficiency of the light emitting device in the third sub-pixel P3 is greater than the luminous efficiency of the light emitting device in the first sub-pixel P1, the luminous efficiency of the light emitting device in the third sub-pixel P3 is greater than the luminous efficiency of the light emitting device in the second sub-pixel P2, and the luminous efficiency of the light emitting device in the second sub-pixel P2 is greater than the luminous efficiency of the light emitting device in the first sub-pixel P1.

For example, the first sub-pixel P1 is a blue sub-pixel, the second sub-pixel P2 is a red sub-pixel, and the third sub-pixel P3 is a green sub-pixel. Certainly, the embodiments of the present application include but are not limited thereto.

In some examples, the area of the orthographic projection on the driving base board 100 of the effective light emitting region of the first sub-pixel P1 is greater than the area of the orthographic projection on the driving base board 100 of the effective light emitting region of the second sub-pixel P2, and the area of the orthographic projection on the driving base board 100 of the effective light emitting region of the second sub-pixel P2 is greater than the area of the orthographic projection on the driving base board 100 of the effective light emitting region of the third sub-pixel P3. Certainly, the embodiments of the present application include but are not limited thereto, and the areas of the effective light emitting regions of the sub-pixels may be configured according to practical demands.

In addition, that the thickness of the first optical-adjustment pattern 3A, the thickness of the second optical-adjustment pattern 3B and the thickness of the third optical-adjustment pattern 3C are at least partially unequal includes but is not limited to the following cases:

In the first case, as shown in FIG. 7, the thickness of the first optical-adjustment pattern 3A is greater than the thickness of the second optical-adjustment pattern 3B and the thickness of the third optical-adjustment pattern 3C, and the thickness of the second optical-adjustment pattern 3B and the thickness of the third optical-adjustment pattern 3C are substantially equal.

In the second case, as shown in FIG. 8, the thickness of the first optical-adjustment pattern 3A is greater than the thickness of the second optical-adjustment pattern 3B, and the thickness of the second optical-adjustment pattern 3B is greater than the thickness of the third optical-adjustment pattern 3C.

Throughout the present application, the “thickness” refers to the dimension of a component in the direction perpendicular to the driving base board 100.

In the embodiments of the present application, because the luminous efficiencies of the light emitting devices in the sub-pixels of different colors are unequal, by configuring that the thickness of the first optical-adjustment pattern 3A, the thickness of the second optical-adjustment pattern 3B and the thickness of the third optical-adjustment pattern 3C are at least partially unequal, not only the overall brightness of the second displaying region AA2 is increased by using the micro-cavity effect, but also, according to the original luminous efficiencies of the devices of the sub-pixels of different colors, unequal thicknesses of the optical-adjustment patterns can be configured for the sub-pixels of different colors, to regulate the degrees of the micro-cavity effects of the sub-pixels of different colors, which serves to regulate the frame colors and improve the image quality, and can also reduce the power consumption and prolong the service life of the sub-pixels.

For example, taking the case as an example where the first sub-pixel P1 is a blue sub-pixel, the second sub-pixel P2 is a red sub-pixel, and the third sub-pixel P3 is a green sub-pixel, when the luminous efficiency of the light emitting device in the third sub-pixel P3 is greater than the luminous efficiency of the light emitting device in the second sub-pixel P2, and the luminous efficiency of the light emitting device in the second sub-pixel P2 is greater than the luminous efficiency of the light emitting device in the first sub-pixel P1, by configuring that the thickness of the first optical-adjustment pattern 3A is greater than the thickness of the second optical-adjustment pattern 3B, and the thickness of the second optical-adjustment pattern 3B is greater than the thickness of the third optical-adjustment pattern 3C, so that the first sub-pixel P1, which originally has the lowest luminous efficiency, has the strongest micro-cavity effect, which compensates for the defect of the first sub-pixel P1 of the low luminous efficiency to a large extent, thereby the power consumption is reduced and the cost is reduced.

In the at least one display panel according to the present application, the refractive index of the first optical-adjustment pattern 3A, the refractive index of the second optical-adjustment pattern 3B and the refractive index of the third optical-adjustment pattern 3C are at least partially unequal.

As an example, the refractive index of the first optical-adjustment pattern 3A and the refractive index of the second optical-adjustment pattern 3B are unequal. Alternatively, the refractive index of the first optical-adjustment pattern 3A and the refractive index of the third optical-adjustment pattern 3C are unequal. Alternatively, the refractive index of the second optical-adjustment pattern 3B and the refractive index of the third optical-adjustment pattern 3C are unequal. Alternatively, the refractive index of the first optical-adjustment pattern 3A, the refractive index of the second optical-adjustment pattern 3B and the refractive index of the third optical-adjustment pattern 3C are unequal to each other.

In the at least one display panel according to the present application, as shown in FIGS. 7, 8, 9, 10, 11, 15, 16 and 18, each of the first optical-adjustment pattern 3A, the second optical-adjustment pattern 3B and the third optical-adjustment pattern 3C includes at least a conducting sub-layer (for example, the film layer labeled as 34). The conducting sub-layers are electrically connected to the first electrode 1, and there is a gap between the conducting sub-layers in two neighboring sub-pixels.

As an example, the material of the conducting sub-layer may be a light-transmitting conducting material, for example, a metal oxide, including but not limited to indium tin oxide (ITO) and indium zinc oxide (IZO).

Because the conducting sub-layer of each of the sub-pixels is electrically connected to the first electrode 1 that corresponds to the conducting sub-layer, by configuring that there is a gap between the conducting sub-layers in two neighboring sub-pixels, it is prevented that the conducting sub-layers of the two sub-pixels are conducted with each other, thereby short circuiting between the first electrodes 1 of two neighboring sub-pixels is prevented.

At least one of the first optical-adjustment pattern 3A, the second optical-adjustment pattern 3B and the third optical-adjustment pattern 3C further includes an inorganic sub-layer, and the inorganic sub-layer is located between the conducting sub-layer and the first electrode.

The material of the inorganic sub-layer is not limited herein. As an example, the material of the inorganic sub-layer may include an inorganic conducting material and/or an inorganic insulating material.

As an example, the material of the inorganic sub-layer may include at least one of silicon nitride, silicon oxide, silicon oxynitride, titanium nitride, titanium oxide and aluminium oxide.

By configuring that the inorganic sub-layer is located between the conducting sub-layer and the first electrode, the thicknesses of the first optical-adjustment pattern 3A, the second optical-adjustment pattern 3B and the third optical-adjustment pattern 3C can be regulated by using the inorganic sub-layer, thereby the effective cavity lengths of the micro-cavity structures formed in the first sub-pixel P1, the second sub-pixel P2 and the third sub-pixel P3 within the second displaying region AA2 are regulated, so that the brightnesses of the light rays exiting from the first sub-pixel P1, the second sub-pixel P2 and the third sub-pixel P3 within the second displaying region AA2 are regulated, thereby the overall brightness of the second displaying region AA2 is regulated.

In the at least one display panel according to the present application, within the second displaying region AA2, in the direction perpendicular to the luminescence-function layer 5, the distance from the first electrode 1 to the second electrode 6 of the first sub-pixel P1 is a first distance J1. The distance from the first electrode 1 to the second electrode 6 of the second sub-pixel P2 is a second distance J2. The distance from the first electrode 1 to the second electrode 6 of the third sub-pixel P3 is a third distance J3. The first distance J1, the second distance J2 and the third distance J3 are at least partially unequal.

As an example, the first distance J1 and the second distance J2 are substantially equal, and both of the first distance J1 and the second distance J2 are greater than the third distance J3.

As an example, the second distance J2 and the third distance J3 are substantially equal, and both of the second distance J2 and the third distance J3 are less than the first distance.

As an example, as shown in FIG. 15, the first distance J1, the second distance J2 and the third distance J3 are unequal to each other.

The first distance J1, the second distance J2 and the third distance J3 are equivalent to the d2 in the formula

$$\vert d 2 − \frac{n λ}{2 N 2} \vert$$

of the effective cavity lengths of the micro-cavity effects of the first sub-pixel P1, the second sub-pixel P2 and the third sub-pixel P3 within the second displaying region AA2 respectively.

In the embodiments of the present application, because the luminous efficiencies of the light emitting devices in the sub-pixels of different colors are unequal, by configuring that the first distance J1, the second distance J2 and the third distance J3 are at least partially unequal, not only the overall brightness of the second displaying region AA2 is increased by using the micro-cavity effect, but also, according to the original luminous efficiencies of the devices of the sub-pixels of different colors, unequal d2 values can be configured for the sub-pixels of different colors, to regulate the degrees of the micro-cavity effects of the sub-pixels of different colors, which serves to regulate the frame colors and improve the image quality, and can also reduce the power consumption and prolong the service life of the sub-pixels.

For example, taking the case as an example where the first sub-pixel P1 is a blue sub-pixel, the second sub-pixel P2 is a red sub-pixel, and the third sub-pixel P3 is a green sub-pixel, when the luminous efficiency of the light emitting device in the third sub-pixel P3 is greater than the luminous efficiency of the light emitting device in the second sub-pixel P2, and the luminous efficiency of the light emitting device in the second sub-pixel P2 is greater than the luminous efficiency of the light emitting device in the first sub-pixel P1, by configuring that the first distance J1 is greater than the second distance J2, and the second distance J2 is greater than the third distance J3, the first sub-pixel P1, which originally has the lowest luminous efficiency, has the strongest micro-cavity effect, which compensates for the defect of the first sub-pixel P1 of the low luminous efficiency to a large extent, thereby the power consumption is reduced and the cost is reduced.

In the at least one display panel according to the present application, as shown in FIGS. 7, 8, 9, 10, 11, 15, 16 and 18, the first optical-adjustment pattern 3A includes a first inorganic sub-layer 31, a second inorganic sub-layer 32, a third inorganic sub-layer 33 and the conducting sub-layer 34 that are located on the first electrode 1 and are sequentially arranged.

As shown in FIG. 8, in the first sub-pixel P1 within the second displaying region AA2, the first optical-adjustment pattern 3A further includes a first through hole (not labeled), the first through hole extends throughout the first inorganic sub-layer 31, the second inorganic sub-layer 32 and the third inorganic sub-layer 33, and the conducting sub-layer 34 is electrically connected to the first electrode 1 via the first through hole.

In an exemplary embodiment, when the auxiliary electrode F is disposed between the first electrode 1 and the first optical-adjustment pattern 3A, the conducting sub-layer 34 in the first optical-adjustment pattern 3A directly is contacted with and is conducted with the auxiliary electrode F via the first through hole, and the auxiliary electrode F is conducted with the first electrode 1.

In the embodiments of the present application, by configuring that the first optical-adjustment pattern 3A includes a first inorganic sub-layer 31, a second inorganic sub-layer 32, a third inorganic sub-layer 33 and the conducting sub-layer 34 that are located on the first electrode 1 and are sequentially arranged, the effective cavity length of the micro-cavity structure formed in the first sub-pixel P1 can be regulated by regulating the thicknesses of the first inorganic sub-layer 31, the second inorganic sub-layer 32, the third inorganic sub-layer 33 and the conducting sub-layer 34, and the refractive index of the first optical-adjustment pattern 3A can be regulated by regulating the materials of the first inorganic sub-layer 31, the second inorganic sub-layer 32, the third inorganic sub-layer 33 and the conducting sub-layer 34, thereby the effective cavity length of the micro-cavity structure formed in the first sub-pixel P1 is further regulated, so that the first sub-pixel P1 within the second displaying region AA2, as compared with the first sub-pixel P1 within the first displaying region AA1, has a stronger micro-cavity effect. Accordingly, the brightness of the displaying light rays within the second displaying region AA2 is increased, so that the brightnesses of the first displaying region AA1 and the second displaying region AA2 tend to be equal, thereby the effect of displaying of the display panel is improved.

In the at least one display panel according to the present application, as shown in FIGS. 7, 8, 9, 10, 11, 15, 16 and 18, the second optical-adjustment pattern 3B includes the first inorganic sub-layer 31, the second inorganic sub-layer 32 and the conducting sub-layer 34 that are located on the first electrode 1 and are sequentially arranged.

As shown in FIG. 8, in the second sub-pixel P2 within the second displaying region AA2, the second optical-adjustment pattern 3B further includes a second through hole, the second through hole extends throughout the first inorganic sub-layer 31 and the second inorganic sub-layer 32, and the conducting sub-layer 34 is electrically connected to the first electrode 1 via the second through hole.

Within local areas, in order to improve the stability of the conduction between the connecting lines or the component elements of the different film layers, a plurality of through holes filled with a conducting material may be disposed between two conducting components. The quantity of the through holes drawn in the drawings according to the present application does not represent a limitation on their quantity, and is merely an exemplary illustration.

The shapes and the arrangement mode of the plurality of through holes (for example, the first through hole and the second through hole) are not limited herein.

As an example, the planar shapes of the through holes may be a rectangle, a circle, an ellipse and so on. The sizes of the plurality of through holes may be equal or unequal.

In an exemplary embodiment, when the auxiliary electrode F is further disposed between the first electrode 1 and the second optical-adjustment pattern 3B, the conducting sub-layer 34 in the second optical-adjustment pattern 3B is directly contacted with and is conducted with the auxiliary electrode F via the first through hole, and the auxiliary electrode F is conducted with the first electrode 1.

In the embodiments of the present application, by configuring that the second optical-adjustment pattern 3B includes the first inorganic sub-layer 31, the second inorganic sub-layer 32 and the conducting sub-layer 34 that are located on the first electrode 1 and are sequentially arranged, the effective cavity length of the micro-cavity structure formed in the second sub-pixel P2 can be regulated by regulating the thicknesses of the first inorganic sub-layer 31, the second inorganic sub-layer 32 and the conducting sub-layer 34, and the refractive index of the second optical-adjustment pattern 3B can be regulated by regulating the materials of the first inorganic sub-layer 31, the second inorganic sub-layer 32 and the conducting sub-layer 34, thereby the effective cavity length of the micro-cavity structure formed in the second sub-pixel P2 is further regulated, so that the second sub-pixel P2 within the second displaying region AA2, as compared with the second sub-pixel P2 within the first displaying region AA1, has a stronger micro-cavity effect. Accordingly, the brightness of the displaying light rays within the second displaying region AA2 is increased, so that the brightnesses of the first displaying region AA1 and the second displaying region AA2 tend to be equal, thereby the effect of displaying of the display panel is improved.

In the at least one display panel according to the present application, as shown in FIGS. 7, 8, 9, 10, 11, 15, 16 and 18, the third optical-adjustment pattern 3C includes the conducting sub-layer 34 located on the first electrode 1, and in the third sub-pixel P3 within the second displaying region AA2, the conducting sub-layer 34 is contacted with and is connected to the first electrode 1.

In an exemplary embodiment, when the auxiliary electrode F is disposed between the first electrode 1 and the third optical-adjustment pattern 3C, the conducting sub-layer 34 in the third optical-adjustment pattern 3C is directly contacted with and is conducted with the auxiliary electrode F via the first through hole, and the auxiliary electrode F is conducted with the first electrode 1.

In the embodiments of the present application, by configuring that the third optical-adjustment pattern 3C includes the conducting sub-layer 34 located on the first electrode 1, the effective cavity length of the micro-cavity structure formed in the third sub-pixel P3 can be regulated by regulating the thickness of the conducting sub-layer 34, and the refractive index of the third optical-adjustment pattern 3C can be regulated by regulating the material of the conducting sub-layer 34, thereby the effective cavity length of the micro-cavity structure formed in the third sub-pixel P3 is further regulated, so that the third sub-pixel P3 within the second displaying region AA2, as compared with the third sub-pixel P3 within the first displaying region AA1, has a stronger micro-cavity effect. Accordingly, the brightness of the displaying light rays within the second displaying region AA2 is increased, so that the brightnesses of the first displaying region AA1 and the second displaying region AA2 tend to be equal, thereby the effect of displaying of the display panel is improved.

It should be noted that, in at least one display panel according to the embodiments of the present application, as shown in FIGS. 7, 8, 9, 10, 11, 15, 16 and 18, within the second displaying region AA2, within all of the areas between two neighboring sub-pixels, for example, the area between the first sub-pixel P1 and the second sub-pixel P2, and the area between the second sub-pixel P2 and the third sub-pixel P3, are provided with the first inorganic sub-layer 31, the second inorganic sub-layer 32, the third inorganic sub-layer 33 and the conducting sub-layer 34. All of the first inorganic sub-layer 31, the second inorganic sub-layer 32 and the third inorganic sub-layer 33 within the region between the two neighboring sub-pixels may be connected together. However, the conducting sub-layer 34 within the region between the two neighboring sub-pixels includes a first part and a second part, and there is a gap between the first part and the second part, to prevent the conducting sub-layer 34 within the region between the two neighboring sub-pixels from short-circuiting the two sub-pixels.

In addition, whether the thicknesses of the first inorganic sub-layers 31 in any two sub-pixels are equal, whether the thicknesses of the second inorganic sub-layers 32 in any two sub-pixels are equal, whether the thicknesses of the third inorganic sub-layers 33 in any two sub-pixels are equal, or whether the thicknesses of the conducting sub-layers 34 in any two sub-pixels are equal is not limited herein.

In the at least one embodiment of the present application, the thicknesses of the first inorganic sub-layers 31 in any two sub-pixels are equal.

In the at least one embodiment of the present application, the thicknesses of the second inorganic sub-layers 31 in any two sub-pixels are equal.

In at least one embodiment of the present application, the thicknesses of the third inorganic sub-layers 33 in any two sub-pixels are equal.

In the at least one embodiment of the present application, the thicknesses of the conducting sub-layers 34 in any two sub-pixels are equal.

In the at least one display panel according to the present application, the refractive index of the first inorganic sub-layer 31, the refractive index of the second inorganic sub-layer 32, the refractive index of the third inorganic sub-layer 33 and the refractive index of the conducting sub-layer 34 are unequal to each other.

In the at least one display panel according to the present application, in the direction away from the first electrode 1, the refractive index of the first inorganic sub-layer 31, the refractive index of the second inorganic sub-layer 32, the refractive index of the third inorganic sub-layer 33 and the refractive index of the conducting sub-layer 34 sequentially increase.

In the direction toward the first electrode 1, the refractive indexes of the first inorganic sub-layer 31, the second inorganic sub-layer 32, the third inorganic sub-layer 33 and the conducting sub-layer 34 gradually decrease.

In the embodiments of the present application, when the light rays emitted by the luminescence-function layer 5 pass through the optical-adjustment layer 3 and are shot to the first electrode 1, in the direction away from the first electrode 1, the refractive index of the first inorganic sub-layer 31, the refractive index of the second inorganic sub-layer 32, the refractive index of the third inorganic sub-layer 33 and the refractive index of the conducting sub-layer 34 sequentially increase; in other words, in the direction toward the first electrode 1, the refractive indexes of the first inorganic sub-layer 31, the second inorganic sub-layer 32, the third inorganic sub-layer 33 and the conducting sub-layer 34 gradually decrease. In this way, in the process during which the light rays pass through the optical-adjustment layer 3 and are shot to the first electrode 1, the light rays are transmitted from the optically denser medium to the optically thinner medium, and can very easily have total reflection, so that the light rays shot to the first electrode 1 are reflected to the light exiting side, which facilitates to intensify the micro-cavity effect and increase the luminous efficiency of the sub-pixels. Therefore, the brightness of the second displaying region AA2 is increased, so that the brightnesses of the first displaying region AA1 and the second displaying region AA2 tend to be equal, thereby the effect of displaying of the display panel is improved.

In the at least one display panel according to the present application, the material of the first inorganic sub-layer 31 includes silicon oxide (SiO₂), the material of the second inorganic sub-layer 32 includes aluminium oxide (Al₂O₃), the material of the third inorganic sub-layer 33 includes silicon nitride (SiNₓ), and the material of the conducting sub-layer 34 includes indium tin oxide (ITO) or indium zinc oxide (IZO).

In the at least one embodiment of the present application, for the regions where the first inorganic sub-layers 31 are disposed, the first inorganic sub-layers 31 are of an integral structure. For the regions where the second inorganic sub-layers 32 are disposed, the second inorganic sub-layers 32 are of an integral structure. For the regions where the third inorganic sub-layers 33 are disposed, the third inorganic sub-layers 33 are of an integral structure.

It should be noted that the integral structure refers to being manufactured in the same manufacturing process by using the same precursor material. The final materials of the two components that correspond to the integral structure may be the same or different. Sharing one component (for example, sharing the second electrode 6) refers to being manufactured in the same manufacturing process by using the same material, and the final materials being the same.

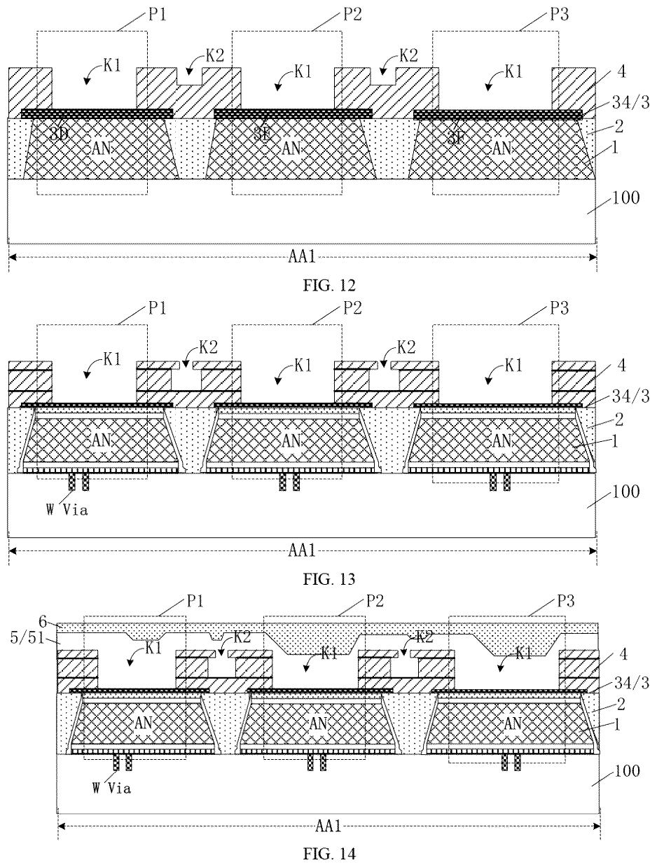

In the at least one display panel according to the present application, as shown in FIGS. 6, 12, 13, 14, 17 and 19, the first optical-adjustment layer includes a fourth optical-adjustment pattern 3D, a fifth optical-adjustment pattern 3E and a sixth optical-adjustment pattern 3F.

Referring to FIGS. 6 and 17, within the first displaying region AA1, the fourth optical-adjustment pattern 3D is located between the luminescence-function layer 5 and the first electrode 1 of the first sub-pixel P1, the fifth optical-adjustment pattern 3E is located between the luminescence-function layer 5 and the first electrode 1 of the second sub-pixel P2, and the sixth optical-adjustment pattern 3F is located between the luminescence-function layer 5 and the first electrode 1 of the third sub-pixel P3. As shown in FIG. 6, the thickness H4 of the fourth optical-adjustment pattern 3D, the thickness H5 of the fifth optical-adjustment pattern 3E and the thickness H6 of the sixth optical-adjustment pattern 3F are substantially equal.

In the at least one display panel according to the present application, the material of the fourth optical-adjustment pattern 3D, the material of the fifth optical-adjustment pattern 3E and the material of the sixth optical-adjustment pattern 3F are the same, and are a light-transmitting conducting material. It may be considered that each of the fourth optical-adjustment pattern 3D, the fifth optical-adjustment pattern 3E and the sixth optical-adjustment pattern 3F includes one conducting sub-layer 34, and the conducting sub-layers 34 in the fourth optical-adjustment pattern 3D, the fifth optical-adjustment pattern 3E and the sixth optical-adjustment pattern 3F are disposed in the same layer as the conducting sub-layers 34 in the first optical-adjustment pattern 3A, the second optical-adjustment pattern 3B and the third optical-adjustment pattern 3C.

The “arranged in the same layer” refers to a structure that is formed by the same time of patterning process from two (or more) components. The materials of the two (or more) components may be the same or different. For example, the precursor materials for forming multiple components that are arranged in the same layer are the same, and the finally formed materials may be the same or different. In the at least one embodiment according to the present application, the final material of the conducting sub-layers 34 in the fourth optical-adjustment pattern 3D, the fifth optical-adjustment pattern 3E and the sixth optical-adjustment pattern 3F is the same as the final material of the conducting sub-layers 34 in the first optical-adjustment pattern 3A, the second optical-adjustment pattern 3B and the third optical-adjustment pattern 3C.

In the first sub-pixel P1 within the first displaying region AA1, the fourth optical-adjustment pattern 3D is contacted with and is connected to the first electrode 1. In the second sub-pixel P2, the fifth optical-adjustment pattern 3E is contacted with and is connected to the first electrode 1. In the third sub-pixel P3, the sixth optical-adjustment pattern 3F is contacted with and is connected to the first electrode 1.

In the at least one display panel according to the present application, as shown in FIGS. 8, 9, 10, 11 and 13-19, the auxiliary electrode F includes a first auxiliary sub-electrode F1 and a second auxiliary sub-electrode F2, the first auxiliary sub-electrode F1 is contacted with the first electrode 1, and the second auxiliary sub-electrode F2 is contacted with the optical-adjustment layer 3. The hardness of the material of the first auxiliary sub-electrode F1 is greater than the hardness of the material of the first electrode 1.

In the at least one embodiment of the present application, the material of the auxiliary electrode F is a light-transmitting conducting material.

In an exemplary embodiment, the material of the first electrode 1 includes aluminum (Al), the material of the first auxiliary sub-layer F1 includes titanium nitride (TiN), and the material of the second auxiliary sub-layer F2 includes indium tin oxide (ITO) or indium zinc oxide (IZO).

In the embodiments of the present application, by configuring that the hardness of the material of the first auxiliary sub-electrode F1 is greater than the hardness of the material of the first electrode 1, the first electrode 1 can be protected, to prevent damage on the first electrode 1 in the practical manufacturing process.

In the at least one display panel according to the present application, as shown in FIGS. 8, 9, 10, 11 and 13-19, each of the sub-pixels further includes an auxiliary conducting layer D and a protecting layer B, the auxiliary conducting layer D includes a third auxiliary sub-electrode F3 and a fourth auxiliary sub-electrode F4, the third auxiliary sub-electrode F3 is located between the first electrode 1 and the fourth auxiliary sub-electrode F4, and the fourth auxiliary sub-electrode F4 is contacted with and is conducted with the driving base board 100. The protecting layer B covers a side face of the first electrode 1.

The material of the third auxiliary sub-electrode F3 is the same as the material of the first auxiliary sub-electrode F1.

As an example, the hardness of the material of the third auxiliary sub-electrode F3 is greater than the hardness of the material of the first electrode 1.

In the embodiments of the present application, by configuring that the hardness of the material of the third auxiliary sub-electrode F3 is greater than the hardness of the material of the first electrode 1, the first electrode 1 can be protected, to prevent damage on the first electrode 1 in the practical manufacturing process.

As an example, the material of the fourth auxiliary sub-electrode F4 includes titanium (Ti), the material of the third auxiliary sub-electrode F3 includes titanium nitride (TiN), and the material of the first electrode 1 includes aluminum (Al). Titanium nitride (TiN) has a higher hardness, and can serve to protect aluminum (Al). The fourth auxiliary sub-electrode F4 is contacted with and is conducted with the driving base board 100. By configuring that the material of the fourth auxiliary sub-electrode F4 includes titanium (Ti), the stability of the contacting and conduction between the fourth auxiliary sub-electrode F4 and the driving base board 100 can be increased, thereby the stability of the conduction between the driving base board 100 and the first electrode 1 is improved and the capacity of driving of the driving circuit is improved.

As an example, the driving base board 100 further includes a plurality of tungsten holes (W Via). By disposing the fourth auxiliary sub-electrode F4, it can be conducted with the tungsten holes (W Via) of the driving base board 100 better, thereby the stability of the conduction between the driving base board 100 and the first electrode 1 is improved.

In the at least one display panel according to the present application, the driving base board 100 includes a plurality of metal layers, and each of the metal layers includes a plurality of conducting patterns. FIG. 3 shows one of the metal layers of the driving base board 100, wherein a data line DL is disposed in that metal layer. The first displaying region AA includes a first region Area1, the second displaying region AA2 includes a second region Area2, and the first region Area1 and the second region Area2 have the same shape and the same area.

As an example, the conducting patterns may include a signal line and a conducting component, for example, the data line DL, a gate line GL and a resetting-signal line Reset Line.

For at least one of the metal layers, for example, a metal layer provided with the data line DL, the area of the part of the conducting patterns (for example, the data line DL) that is located within the first region Area1 is less than the area of the part of the conducting patterns (for example, the data line DL) that is located within the second region Area2.

In the embodiments of the present application, taking the case as an example where the first displaying region AA1 is the splicing-exposure region, because two times of exposure are performed within the splicing-exposure region, the exposure amount that the splicing-exposure region receives is greater than the exposure amount received by the region of the normal exposure. Therefore, as compared with the region of the normal exposure, the conducting patterns within the splicing-exposure region have lower sizes, and higher gaps (Space). Therefore, for each of the metal layers that employ the splicing exposure, the area of the part of the conducting patterns in that metal layer that is located within the first region Area1 is less than the area of the part of the conducting patterns that is located within the second region Area2. The first region Area1 and the second region Area2 have the same shape and the same area, and the conducting patterns that the first region Area1 and the second region Area2 correspond to are substantially the same.

In an exemplary embodiment, for at least one of the metal layers, the line width of the part of a signal line in the metal layer that is located within the first region Area1 is less than the line width of the part of the same type of signal line that is located within the second region Area2.

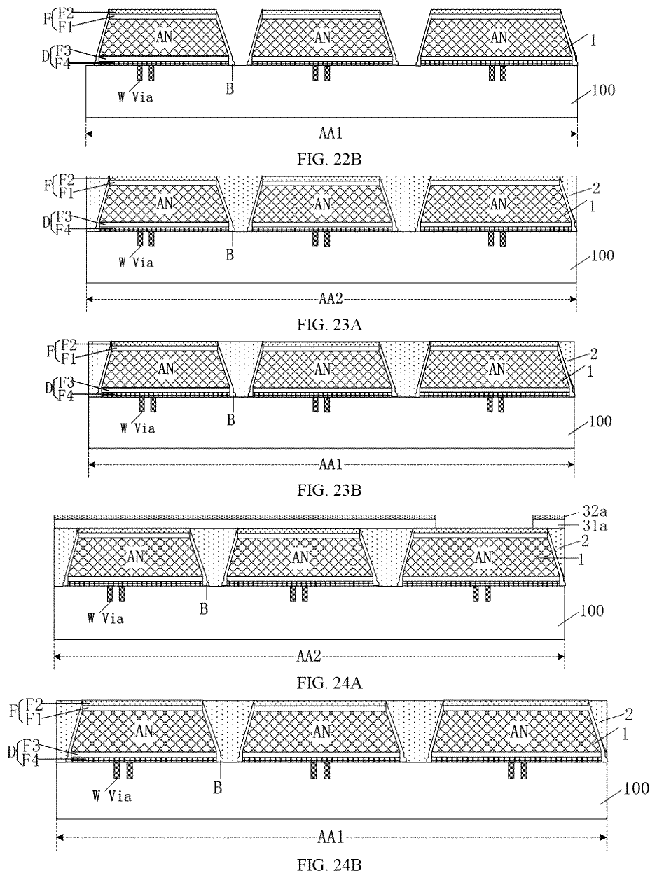

As an example, as shown in FIG. 21, the range of the difference between the line width of the part of a signal line in the metal layer that is located within the first region Area1 and the line width of the part of the same type of signal line that is located within the second region Area2 is 0.1 μm-0.6 μm.

For example, the difference between the line width of the part of a signal line in the metal layer that is located within the first region Area1 and the line width of the part of the same type of signal line that is located within the second region Area2 is 0.2 μm, 0.3 μm, 0.4 μm and 0.5 μm.

FIG. 21 illustratively shows, with the different exposure amounts (Dose), the variation of the difference in the line widths of the part located within the first region Area1 and the part located within the second region Area2 of the same type of signal line. The exposure amount of the practical exposure is not limited in the embodiments of the present application, and may be specifically decided according to practical product designs.

In the at least one display panel according to the present application, as shown in FIGS. 4-19, the display panel further includes a packing layer 2 and a pixel defining layer 4, the packing layer 2 is disposed between the first electrodes 1 of two neighboring sub-pixels, and the optical-adjustment layer 3 covers at least a part of the packing layer 2. The pixel defining layer 4 is located at the side of all of the optical-adjustment layers 3 away from the first electrode 1.

In an exemplary embodiment, the material of the packing layer 2 includes an insulating material, used to separate the first electrodes 1 of two neighboring sub-pixels, thereby short circuiting between two neighboring first electrodes 1 is avoided.

In some embodiments, the upper surface (the surface of the side away from the driving base board 100) of the packing layer 2 is flush with the upper surface of the first electrode 1, so that the subsequent structure has a more even terrain in the manufacturing process, the difficulty in the manufacturing process is reduced, and the yield is increased.

In some embodiments, when the auxiliary electrode F covers the first electrode 1, the upper surface (the surface of the side away from the driving base board 100) of the packing layer 2 is flush with the upper surface of the auxiliary electrode F, so that the subsequent structure has a more even terrain in the manufacturing process, the difficulty in the manufacturing process is reduced, and the yield is increased.

That the optical-adjustment layer 3 covers at least part of the packing layer 2 includes but is not limited to the following cases:

In the first case, as shown in FIG. 17, when the optical-adjustment layer 3 includes merely the conducting sub-layer 34, because the conducting sub-layer 34 is electrically conductive, there is a gap between two neighboring conducting sub-layers 34, and, at this moment, the optical-adjustment layer 3 covers a part of the packing layer 2.

In the second case, as shown in FIG. 7, when the optical-adjustment layer 3 includes at least one of the first inorganic sub-layer 31, the second inorganic sub-layer 32 and the third inorganic sub-layer 33, the optical-adjustment layer 3 may cover the whole of the packing layer 2.

The pixel defining layer 4 includes a plurality of first slots K1 arranged in an array, and at least a part of the luminescence-function layer 5 is disposed in one of the first slots K1. The region enclosed by the orthographic projection on the driving base board 100 of the outer contour of the first slot K1 falls within the orthographic projection of the optical-adjustment layer 3 on the driving base board 100.

The first slots K1 may also be referred to as pixel openings, and the plurality of pixel openings correspond to the plurality of sub-pixels one to one to define the light emitting regions of the plurality of sub-pixels.

The planar shapes of the first slots K1 are not limited herein. Generally, according to the different colors of the sub-pixels, the first slots K1 have different planar shapes.

As an example, the planar shape of the first slot K1 in the first sub-pixel P1, the planar shape of the first slot K1 in the second sub-pixel P2 and the planar shape of the first slot K1 in the third sub-pixel P3 are at least partially different.

As an example, the size of the planar pattern of the first slot K1 in the first sub-pixel P1, the size of the planar pattern of the first slot K1 in the second sub-pixel P2 and the size of the planar pattern of the first slot K1 in the third sub-pixel P3 are at least partially unequal.

As an example, the planar shapes of the first slots K1 may include a polygon, an arc shape, or a combination of a polygon and an arc shape. The combination of a polygon and an arc shape includes a pattern formed by splicing a polygon and an arc shape, or a pattern formed by excavating off part of the area of a polygon or an arc shape. The polygon may include a triangle, a quadrangle, a pentagon and so on. The arc shape may include a sector shape, a circular shape, an elliptical shape, a semicircular shape and so on.

It should be noted that the planar shapes and the sizes of the first slots K1 are related to the aperture ratio of the display panel.

In the at least one display panel according to the present application, for the first slots K1 of the luminescence-function layers provided with the same color, the size of the planar pattern of the part of the first slots K1 that is located within the first displaying region AA1 is greater than or equal to the size of the planar pattern of the part of the first slots K1 that is located within the second displaying region AA2.

As an example, referring to FIGS. 4 and 5, the area S1 of the planar pattern of the first slot K1 in the first sub-pixel P1 within the second displaying region AA2 is less than the area S4 of the planar pattern of the first slot K1 in the first sub-pixel P1 within the first displaying region AA1. The area S2 of the planar pattern of the first slot K1 in the second sub-pixel P2 within the second displaying region AA2 is less than the area S5 of the planar pattern of the first slot K1 in the second sub-pixel P2 within the first displaying region AA1. The area S3 of the planar pattern of the first slot K1 in the third sub-pixel P3 within the second displaying region AA2 is less than the area S6 of the planar pattern of the first slot K1 in the third sub-pixel P3 within the first displaying region AA1.

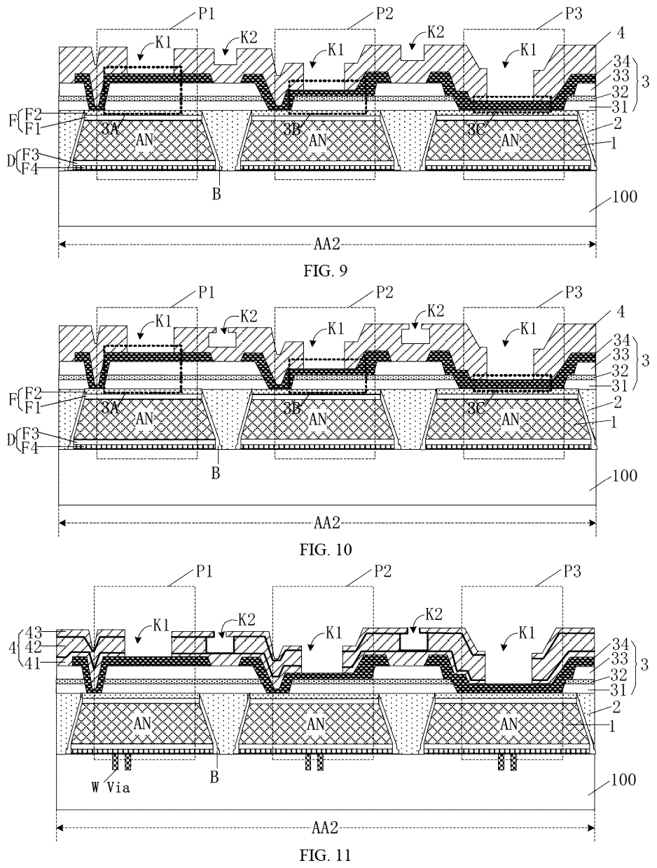

In the at least one display panel according to the present application, as shown in FIGS. 9-11 and 13-19, the pixel defining layer 4 includes a plurality of second slots K2, each of the second slots K2 is disposed between two neighboring first slots K1, and the depth of each of the second slots K2 in the direction perpendicular to the driving base board 100 is less than or equal to the depth of each of the first slots K1 in the direction perpendicular to the driving base board 100.

The planar shapes of the second slots K2 are not limited herein. As an example, the planar shapes of the second slots K2 may include a polygon, an arc shape, or a combination of a polygon and an arc shape. The combination of a polygon and an arc shape includes a pattern formed by splicing a polygon and an arc shape, or a pattern formed by excavating off part of the area of a polygon or an arc shape. The polygon may include a triangle, a quadrangle, a pentagon and so on. The arc shape may include a sector shape, a circular shape, an elliptical shape, a semicircular shape and so on.

In the practical manufacturing process, when the luminescent layer in the luminescence-function layer 5 is manufactured by vapor deposition or ink-jet printing, by disposing the second slot K2 between two neighboring first slots K1, the excessive luminescent-layer material can flow into the second slot K2, to prevent color mixing of the luminescent layers of the two neighboring sub-pixels.

In the at least one display panel according to the present application, as shown in FIGS. 14 and 15, the luminescence-function layer 5 includes one luminescent sub-layer 51, and the second slots K2 are configured to prevent color mixing of the luminescent sub-layers 51 of two neighboring sub-pixels.

In the at least one display panel according to the present application, as shown in FIGS. 16 and 17, the luminescence-function layer 5 includes at least two luminescent sub-layers 51, 53, a charge generating layer 52 is disposed between two neighboring luminescent sub-layers 51, 53, and the second slots K2 are configured to isolate the charge generating layers 52 of two neighboring sub-pixels.

In the display panel according to the embodiments of the present disclosure, by disposing the second slot K2 between neighboring sub-pixels, and causing the charge generating layers 52 in the luminescence-function layers 5 to be disconnected at the position where the second slot K2 is located, interference between the neighboring sub-pixels caused by the charge generating layer 52 of a higher electric conductivity is avoided. In another aspect, because the display panel can prevent interference between the neighboring sub-pixels by using the second slots K2, the display panel can, while employing the design of double-layer luminescence (Tandem EL), increase the pixel density. Therefore, the display panel can have the advantages such as a long life, a low power consumption, a high brightness and a high resolution.

It should be noted that the “neighboring sub-pixels” as used herein refers to that no other sub-pixel is disposed between two sub-pixels.

When the luminescence-function layer 5 includes at least two luminescent sub-layers, in the direction perpendicular to the driving base board 100, the luminescence-function layer 5 further includes a plurality of functional sub-layers. The plurality of functional sub-layers include a hole transporting layer matching with a first luminescent sub-layer 51 of a different color, the first luminescent sub-layer 51 of a different color, the charge generating layer 52, a hole outputting layer matching with a second luminescent sub-layer 53 of a different color, the second luminescent sub-layer 53 of a different color, an electron transporting layer and an electron injection layer. The specific structure of such a design of double-layer luminescence (Tandem EL) may refer to the description in the related art, and is not discussed further herein.

It should be noted that, for a display panel of the design of double-layer luminescence (Tandem EL), in some examples, there may be a gap between the luminescent sub-layers of two neighboring sub-pixels. In some examples, the luminescent sub-layers of two neighboring sub-pixels may be connected to each other. In some examples, there may be an overlapping region between the luminescent sub-layers of two neighboring sub-pixels.

In addition, the film layers such as the hole transporting layer, the electron blocking layer, the hole outputting layer, the electron transporting layer and the electron injection layer may be collectively referred to as communicated layers. The communicated layers of all of the sub-pixels of the display panel may be shared; in other words, the communicated layers of any two neighboring sub-pixels are connected integrally.

The charge generating layer 52 includes an N-type doped layer for generating holes and a P-type doped layer for generating electrons that are arranged in layer configuration. For example, the charge generating layer may include an N-type-doped organic layer/P-type-doped organic layer, for example, BPhen:Cs/NPB:F4-TCNQ, Alq₃:Li/NPB:FeCl₃, TPBi:Li/NPB:FeCl₃ and Alq₃:Mg/m-MTDATA:F4-TCNQ.

Certainly, the embodiments of the present application include but are not limited thereto. The material of the charge generating layer may also include an N-type-doped organic layer/inorganic metal oxide, for example, Alq₃:Mg/WO₃, Bphen:Li/MoO₃, BCP:LiN₂O₅ and BCP:Cs/V₂O₅, or an N-type-doped organic layer/organic layer, for example, Alq₃:Li/HAT-CN, or a non-doped material, for example, F₁₆CuPc/CuPc and Al/WO₃/Au.

For example, the material of the luminescent sub-layer may be selected from a pyrene derivative, an anthracene derivative, a fluorene derivative, a perylene derivative, a styrylamine derivative, a metal complex and so on.

For example, the material of the hole injection layer may include an oxide, for example, a molybdenum oxide, a titanium oxide, a vanadium oxide, a rhenium oxide, a ruthenium oxide, a chromium oxide, a zirconium oxide, a hafnium oxide, a tantalum oxide, a silver oxide, a tungsten oxide and a manganese oxide.

For example, the material of the hole injection layer may also include an organic material, for example, hexacyanohexaazatriphenylene, 2,3,5,6-tetrafluoro-7,7,8,8-tetracyano-p-quinodimethane (F4TCNQ), and 1,2,3-tri[(cyano)(4-cyano-2,3,5,6-tetrafluorophenyl)methylene]cyclopropane.

For example, the material of the hole transporting layer may include an arylamine-type material and a dimethylfluorene or carbazole material having the characteristic of hole transportation, for example, 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluorene-9-yl)triphenylamine (BAFLP), 4,4′-bis[N-(9,9-dimethylfluorene-2-yl)-N-phenylamino]biphenyl (DFLDPBi), 4,4′-di(9-carbazolyl) biphenyl (CBP), and 9-phenyl-3-[4-(10-phenyl-9-anthryl)phenyl]-9H-carbazole (PCzPA).

For example, the material of the electron transporting layer may include an aromatic heterocyclic compound, for example, a benzimidazole derivative, an imidazole derivative, a pyrimidine derivative, an azine derivative, a quinoline derivative, an isoquinoline derivative and a phenanthroline derivative.

For example, the material of the electron injection layer may be an alkali metal, a metal, or a compound thereof, for example, lithium fluoride (LiF), ytterbium (Yb), magnesium (Mg) and calcium (Ca).

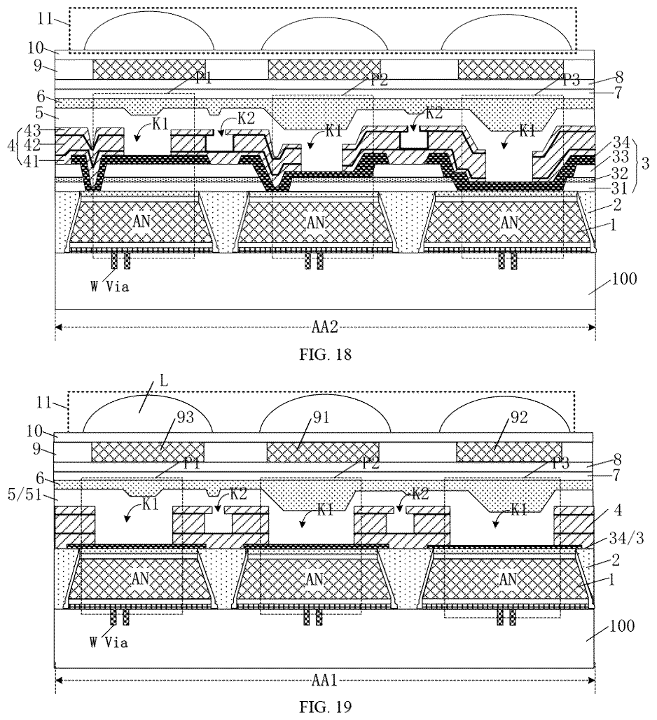

In the at least one display panel according to the present application, as shown in FIG. 18, the pixel defining layer 4 includes a first sub-layer 41, a second sub-layer 42 and a third sub-layer 43 that are sequentially arranged in the direction away from the first electrode 1. Each of the second slots K2 includes an opening and a bottom, and a size of the pattern enclosed by an edge of the opening is less than or equal to a size of a shape enclosed by an outer contour of the bottom.

In an exemplary embodiment, as shown in FIG. 18, the depth of the second slot K2 is substantially equal to the sum of the thicknesses of the second sub-layer 42 and the third sub-layer 43.

In an exemplary embodiment, the thickness of the second sub-layer 42 is greater than the thickness of the first sub-layer 41, and the thickness of the second sub-layer 42 is greater than the thickness of the third sub-layer 43.

As an example, the material of the pixel defining layer 4 may include an organic material, for example, polyimide, polymethyl methacrylate and polyethylene terephthalate.

As an example, the material of the pixel defining layer 4 may include an inorganic material, for example, at least one of silicon oxide, silicon nitride and silicon oxynitride.

For example, the material of the first sub-layer 41 of the pixel defining layer 4 is silicon oxide, the material of the second sub-layer 42 of the pixel defining layer 4 is silicon nitride, and the material of the third sub-layer 43 of the pixel defining layer 4 is silicon oxide.

In the embodiments of the present application, when the luminescence-function layer 5 is manufactured by ink-jet printing, when the printing ink deviates, the printing ink flows into the second slot K2. By configuring that each of the second slots K2 includes an opening and a bottom, and the size of the pattern enclosed by the edge of the opening is less than or equal to the size of the shape enclosed by the outer contour of the bottom, in this way, overflowing of the printing ink inside the second slots K2 can be avoided, and thus color mixing of the printing ink in the two neighboring sub-pixels can be avoided.

In the at least one display panel according to the present application, as shown in FIGS. 18 and 19, the display panel further includes a packaging layer (for example, including packaging sub-layers 8, 10), a color light filtering layer 9 and a lens layer 11. The packaging layer covers all of the second electrodes 6. The packaging layer includes at least two packaging sub-layers, and the color light filtering layer 9 is located between the two packaging sub-layers 8, 10. The lens layer 11 includes a plurality of lens components L, the lens components L are disposed within the first displaying region AA1 and/or the second displaying region AA2, and the lens components L are located at the side of the color light filtering layer 9 away from the first electrode 1.

In an exemplary embodiment, the display panel may further include a film layer 7. The film layer 7 may be a buffer layer or a planarizing layer. The buffer layer is used to cover the cathode (the second electrode 6), so that subsequently the deposition of the packaging layer is easier. The planarizing layer serves for planarization.

The color light filtering layer 9 includes a red light filtering pattern 91, a green light filtering pattern 92, a blue light filtering pattern 93, and a black-matrix pattern located between any two of the red light filtering pattern 91, the green light filtering pattern 92 and the blue light filtering pattern 93.

That the lens components L are disposed within the first displaying region AA1 and/or the second displaying region AA2 includes the following cases:
the lens components L are disposed within the first displaying region AA1;
the lens components L are disposed within the second displaying region AA2; and
the lens components L are disposed within the first displaying region AA1 and the second displaying region AA2.

The figures according to the embodiments of the present application are illustrated by taking the case as an example where the lens components L are disposed within the first displaying region AA1 and the second displaying region AA2.

In the embodiments of the present application, according to practical situations, the lens components L may be disposed within the first displaying region AA1 and/or the second displaying region AA2, which can further increase the luminous efficiency of the display panel, and improve the brightness uniformity of the display panel.

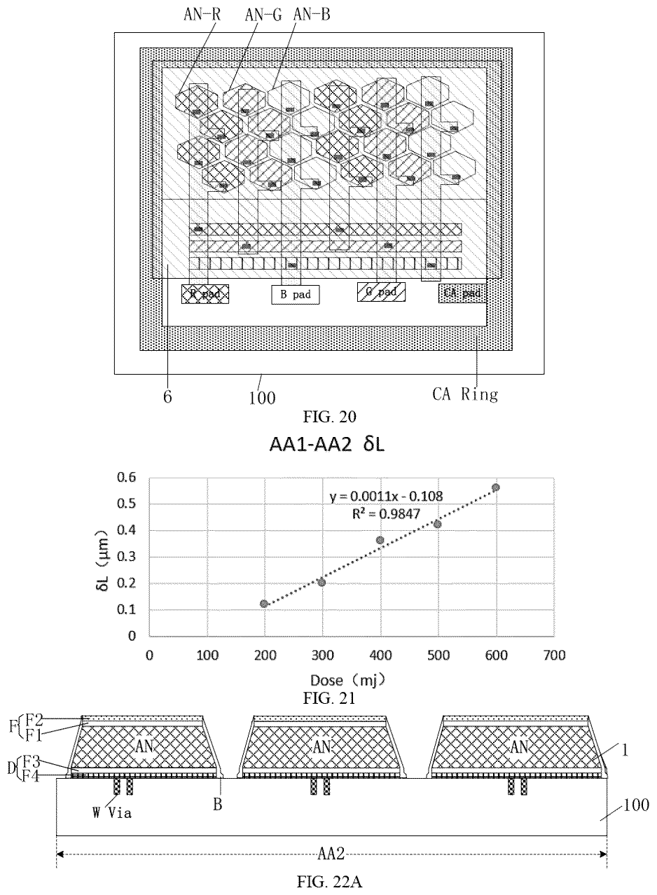

FIG. 20 provides a top structural diagram of a display panel. The at least one display panel according to the embodiments of the present application further includes a cathode ring (CA Ring). The CA Ring surrounds a displaying region AA and a bonding region BD of the display panel. The second electrode (the cathode) 6 is lap-joined to the CA Ring and is electrically connected to the CA Ring.

A plurality of bonding terminals are disposed within the bonding region, for example, a first bonding terminal R pad for connecting the anodes AN-R of all of the red sub-pixels, a second bonding terminal G pad for connecting the anodes AN-G of all of the green sub-pixels, a third bonding terminal B pad for connecting the anodes AN-B of all of the blue sub-pixels, and a fourth bonding terminal CA pad for connecting the cathodes of all of the sub-pixels.

Certainly, the display panel may further include other components. Merely the components that are relevant to the inventiveness are described herein, and the other components included by the display panel may refer to the description in the related art.

A displaying device is provided by the embodiment of the present application, wherein the displaying device includes the display panel stated above.

The displaying device according to the embodiments of the present application may be an OLED displaying device. The OLED displaying device may include a glass-based OLED displaying device and a silicon-based OLED displaying device.

In addition, the displaying device may be a displaying device such as an OLED display, and any product or component having the function of displaying and including the displaying device, such as a television set, a digital camera, a mobile phone and a tablet personal computer.

In the displaying device according to the embodiments of the present application, because the aperture ratio of the part of the display panel that is located within the first displaying region AA1 and the aperture ratio of the part of the display panel that is located within the second displaying region AA2 are unequal, the displaying brightnesses of the first displaying region AA1 and the second displaying region AA2 might be unequal. By disposing the optical-adjustment layer 3 in the sub-pixels, the thicknesses of at least some of the optical-adjustment layers 3 are unequal. The displaying light rays form the micro-cavity effect between the first electrode 1 and the second electrode 6, and the thicknesses of the optical-adjustment layers 3 are unequal, so that the effective cavity lengths of the micro-cavities are unequal. Therefore, the brightnesses of the different regions are regulated by the degrees of the micro-cavity effects, so that the influence on the brightness by the micro-cavity effect and the influence on the brightness by the aperture ratio reach a balance, which finally causes the displaying brightness of the part of the display panel that is located within the first displaying region AA1 and the displaying brightness of the part of the display panel that is located within the second displaying region AA2 to be equal, thereby the uniformity of the brightness of the display panel is increased, and the effect of displaying is improved.

A manufacturing method of a display panel is provided by an embodiment of the present application, applied to the manufacturing of the display panel stated above. The specific method includes:

1. The driving base board 100 is provided. The driving base board 100 may be a complementary metal oxide semiconductor (CMOS) base board.

As shown in FIGS. 22A and 22B, the structures of the part of the driving base board 100 that is located within the first displaying region AA1 and the part of the driving base board 100 that is located within the second displaying region AA2 are the same.

2. As shown in FIGS. 22A and 22B, the auxiliary conducting layer D, the first electrode 1 and the auxiliary electrode F are formed sequentially on the driving base board 100.

3. The protecting layer B is formed. The protecting layer B covers a side face of the first electrode 1.

The protecting layer B may be obtained by the processes of film formation, glue spreading, exposure, development and etching. The protecting layer B is used to prevent the first electrode 1 from being corroded.

4. A filling and leveling up (Lateral Height Coverage, LHC) process is performed, to form the packing layer 2 shown in FIGS. 23A and 23B.

In practical applications, a silicon-oxide thin film may be formed firstly by deposition, and subsequently glue spreading, exposure, development and etching are performed to perform patterning treatment to the silicon-oxide layer, to obtain the packing layer 2 shown in FIGS. 23A and 23B.

5. A silicon-oxide thin film and an aluminium-oxide thin film are sequentially formed, and simultaneously patterning treatment is performed to the silicon-oxide thin film and the aluminium-oxide thin film, to obtain the intermediate structures 31a, 32a shown in FIGS. 24A and 24B.

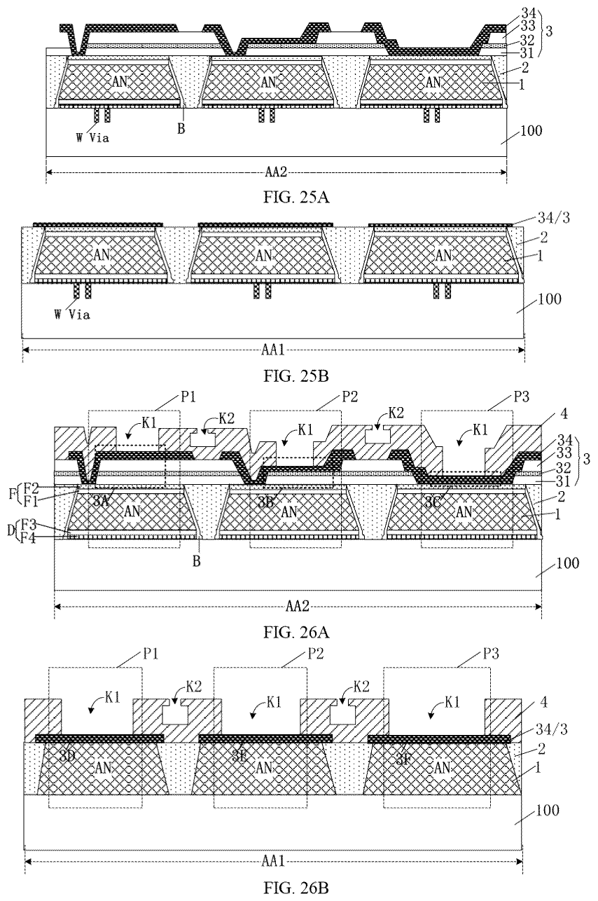

6. A silicon-nitride thin film is formed, and patterning treatment is performed to the silicon-nitride thin film, to obtain the third inorganic sub-layer 33 shown in FIG. 25A. Subsequently, patterning treatment is performed to the intermediate structures 31a, 32a, to obtain the first inorganic sub-layer 31 and the second inorganic sub-layer 32 shown in FIG. 25A.

7. The conducting sub-layer 34 shown in FIGS. 25A and 25B is formed.

8. The pixel defining layer 4 shown in FIGS. 26A and 26B is formed by using the PECVD process. The first slots K1 (also referred to as pixel openings) are formed by etching.

9. The second slots K2 shown in FIGS. 26A and 26B are formed by the etching process.

After the second slots K2 have been formed, subsequently the other film layers such as the luminescence-function layer 5 and the second electrode 6 shown in FIGS. 18 and 19 are formed. The processes for manufacturing the subsequent components of the display panel may refer to the description in the related art, and are not discussed further herein.

In the display panel manufactured in the embodiments of the present application, because the aperture ratio of the part of the display panel that is located within the first displaying region AA1 and the aperture ratio of the part of the display panel that is located within the second displaying region AA2 are unequal, the displaying brightnesses of the first displaying region AA1 and the second displaying region AA2 might be unequal. By disposing the optical-adjustment layer 3 in the sub-pixels, the thicknesses of at least some of the optical-adjustment layers 3 are unequal. The displaying light rays form the micro-cavity effect between the first electrode 1 and the second electrode 6, and the thicknesses of the optical-adjustment layers 3 are unequal, so that the effective cavity lengths of the micro-cavities are unequal. Therefore, the brightnesses of the different regions are regulated by the degrees of the micro-cavity effects, so that the influence on the brightness by the micro-cavity effect and the influence on the brightness by the aperture ratio reach a balance, which finally causes the displaying brightness of the part of the display panel that is located within the first displaying region AA1 and the displaying brightness of the part of the display panel that is located within the second displaying region AA2 to be equal, thereby the uniformity of the brightness of the display panel is increased, and the effect of displaying is improved.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A display panel, comprising a first displaying region and a second displaying region;
each of the first displaying region and the second displaying region comprises a driving base board and a plurality of pixel units that are located on the driving base board and are arranged in an array, each of the plurality of pixel units comprises a plurality of sub-pixels, and each of the plurality of the sub-pixels comprises:
a first electrode configured to be capable of reflecting light rays;
an optical-adjustment layer located at one side of the first electrode;
a luminescence-function layer located at one side of the optical-adjustment layer away from the first electrode; and
a second electrode covering the luminescence-function layer and configured to be capable of transmitting and reflecting light rays; and
for the sub-pixels of a same color,
$$\vert d 1 − \frac{n λ}{2 N 1} \vert > \vert d 2 − \frac{n λ}{2 N 2} \vert ,$$
wherein d1 is a distance from the first electrode to the second electrode of the sub-pixels within the first displaying region, N1 is an effective refractive index from the first electrode to the second electrode of the sub-pixels within the first displaying region, n is a positive integer, λ is a peak wavelength of the color, d2 is a distance from the first electrode to the second electrode of each of the sub-pixels within the second displaying region, and N2 is an effective refractive index from the first electrode to the second electrode of the sub-pixels within the second displaying region.

2. The display panel according to claim 1, wherein within the second displaying region, for the sub-pixels of the same color,
$$\vert d 2 − \frac{n λ}{2 N 2} \vert = 0.$$

3. The display panel according to claim 1, wherein for the sub-pixels of the same color, the effective refractive index from the first electrode to the second electrode of the sub-pixels within the first displaying region and the effective refractive index from the first electrode to the second electrode of the sub-pixels within the second displaying region are equal, and the distance from the first electrode to the second electrode of the sub-pixels within the first displaying region and the distance from the first electrode to the second electrode of the sub-pixels within the second displaying region are unequal.

4. The display panel according to claim 1, wherein for the sub-pixels of the same color, the distance from the first electrode to the second electrode of the sub-pixels within the first displaying region and the distance from the first electrode to the second electrode of the sub-pixels within the second displaying region are equal; and the effective refractive index from the first electrode to the second electrode of the sub-pixels within the first displaying region and the effective refractive index from the first electrode to the second electrode of the sub-pixels within the second displaying region are unequal.

5. The display panel according to claim 1, wherein the second displaying region is divided by the first displaying region into a third displaying sub-region and a fourth displaying sub-region that are discontinuous;
the first displaying region comprises a middle region and edge regions located at two sides of the middle region, and the edge regions are adjacent to the third displaying sub-region or the fourth displaying sub-region; and
within the first displaying region, in directions from the middle region pointing to the edge regions, for the sub-pixels of the same color,
$$\vert d 1 − \frac{n λ}{2 N 1} \vert$$
gradually increases or gradually decreases.

6. The display panel according to claim 5, wherein in a direction from the first displaying region pointing to the third displaying sub-region, a quantity of the sub-pixels disposed within the first displaying region is less than or equal to 10.

7. The display panel according to claim 3, wherein the optical-adjustment layer comprises a first optical-adjustment layer and a second optical-adjustment layer, the first optical-adjustment layer is located within the first displaying region, the second optical-adjustment layer is located within the second displaying region, and for some of the sub-pixels of the same color, a thickness of the first optical-adjustment layer and a thickness of the second optical-adjustment layer are unequal.

8. The display panel according to claim 1, wherein a reflectivity of a part of the driving base board that is located within the first displaying region is less than a reflectivity of a part of the driving base board that is located within the second displaying region.

9. The display panel according to claim 8, wherein each of the sub-pixels comprises an auxiliary electrode, and the auxiliary electrode is located between the first electrode and the optical-adjustment layer; and
a transmittance of a part of the auxiliary electrode that is located within the first displaying region is less than or equal to a transmittance of a part of the auxiliary electrode that is located within the second displaying region.

10. The display panel according to claim 7, wherein for the sub-pixels of the same color, a refractive index of the first optical-adjustment layer is less than or equal to a refractive index of the second optical-adjustment layer.

11. The display panel according to claim 7, wherein the thickness of the first optical-adjustment layer or the thickness of the second optical-adjustment layer is zero.

12. The display panel according to claim 7, wherein each of the plurality of the pixel units comprises a first sub-pixel, a second sub-pixel and a third sub-pixel, and the second optical-adjustment layer comprises a first optical-adjustment pattern, a second optical-adjustment pattern and a third optical-adjustment pattern;
within the second displaying region, the first optical-adjustment pattern is located between the luminescence-function layer and the first electrode of the first sub-pixel, the second optical-adjustment pattern is located between the luminescence-function layer and the first electrode of the second sub-pixel, and the third optical-adjustment pattern is located between the luminescence-function layer and the first electrode of the third sub-pixel; and
a thickness of the first optical-adjustment pattern, a thickness of the second optical-adjustment pattern and a thickness of the third optical-adjustment pattern are at least partially unequal.

13. The display panel according to claim 12, wherein a refractive index of the first optical-adjustment pattern, a refractive index of the second optical-adjustment pattern and a refractive index of the third optical-adjustment pattern are at least partially unequal.

14. The display panel according to claim 13, wherein each of the first optical-adjustment pattern, the second optical-adjustment pattern and the third optical-adjustment pattern comprises at least a conducting sub-layer; the conducting sub-layers are electrically connected to the first electrode, and there is a gap between the conducting sub-layers in two neighboring sub-pixels; and
at least one of the first optical-adjustment pattern, the second optical-adjustment pattern and the third optical-adjustment pattern further comprises an inorganic sub-layer, and the inorganic sub-layer is located between the conducting sub-layer and the first electrode.

15. The display panel according to claim 14, wherein within the second displaying region, in a direction perpendicular to the luminescence-function layer, a distance from the first electrode to the second electrode of the first sub-pixel is a first distance; a distance from the first electrode to the second electrode of the second sub-pixel is a second distance; a distance from the first electrode to the second electrode of the third sub-pixel is a third distance;
wherein the first distance, the second distance and the third distance are at least partially unequal.

16. The display panel according to claim 14, wherein the first optical-adjustment pattern comprises a first inorganic sub-layer, a second inorganic sub-layer, a third inorganic sub-layer and the conducting sub-layer that are located on the first electrode and are sequentially arranged; and
in the first sub-pixel within the second displaying region, the first optical-adjustment pattern further comprises a first through hole, the first through hole extends throughout the first inorganic sub-layer, the second inorganic sub-layer and the third inorganic sub-layer, and the conducting sub-layer is electrically connected to the first electrode via the first through hole.

17. The display panel according to claim 16, wherein the second optical-adjustment pattern comprises the first inorganic sub-layer, the second inorganic sub-layer and the conducting sub-layer that are located on the first electrode and are sequentially arranged; and
in the second sub-pixel within the second displaying region, the second optical-adjustment pattern further comprises a second through hole, the second through hole extends throughout the first inorganic sub-layer and the second inorganic sub-layer, and the conducting sub-layer is electrically connected to the first electrode via the second through hole.

18. The display panel according to claim 17, wherein the third optical-adjustment pattern comprises the conducting sub-layer located on the first electrode, and in the third sub-pixel within the second displaying region, the conducting sub-layer is contacted with and is connected to the first electrode.

19. The display panel according to claim 18, wherein a refractive index of the first inorganic sub-layer, a refractive index of the second inorganic sub-layer, a refractive index of the third inorganic sub-layer and a refractive index of the conducting sub-layer are unequal to each other.

20-31. (canceled)

32. A displaying device, wherein the displaying device comprises the display panel according to claim 1.
